(19) United States
(12) Patent Application Publication
(10) Pub. No.: US 2025/0334736 A1
(43) Pub. Date: Oct. 30, 2025

(54) PHOTONIC SEMICONDUCTOR PACKAGE AND METHOD OF FORMING THE SAME

(71) Applicant: Taiwan Semiconductor Manufacturing Co., Ltd., Hsinchu (TW)

(72) Inventors: Chen-Hua Yu, Hsinchu (TW); Tung-Liang Shao, Hsinchu (TW); Yu-Sheng Huang, Hemei Township (TW)

(21) Appl. No.: 19/258,019

(22) Filed: Jul. 2, 2025

Related U.S. Application Data
(63) Continuation of application No. 18/431,187, filed on Feb. 2, 2024.
(60) Provisional application No. 63/589,366, filed on Oct. 11, 2023.

(51) Int. Cl. G02B 6/12; G02B 6/13

(52) U.S. Cl. CPC G02B 6/12004; G02B 6/13

(57) ABSTRACT

A package includes an interposer; a photonic interconnect structure connected to the interposer, wherein the photonic interconnect structure includes: photonic components; waveguides that are optically coupled to the photonic components; and an electronic die that is electrically coupled to the photonic components; and dies electrically connected to the interposer, wherein the dies are electrically coupled to the photonic interconnect structure through the interposer.

### PRIORITY CLAIM AND CROSS-REFERENCE

This application is a continuation of U.S. patent application Ser. No. 18/431,187, filed on Feb. 2, 2024, which claims the benefits of U.S. Provisional Application No. 63/589,366, filed on Oct. 11, 2023, each application is hereby incorporated herein by reference in its entirety.

### BACKGROUND

Optical signaling and processing are typically combined with electrical signaling and processing to provide full-fledged applications. For example, optical fibers may be used for long-range signal transmission, and electrical signals may be used for short-range signal transmission as well as processing and controlling. Accordingly, devices integrating long-range optical components and short-range electrical components are formed for the conversion between optical signals and electrical signals, as well as the processing of optical signals and electrical signals. Packages thus may include both optical (photonic) components and electronic devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, and 3 illustrate intermediate steps in the formation of a photonic interconnect structure, in accordance with some embodiments.

FIGS. 4A, and 4B illustrate a photonic interconnect structure, in accordance with some embodiments.

FIG. 5 illustrates an interposer, in accordance with some embodiments.

FIG. 6 illustrates a cross-sectional view of a photonic package, in accordance with some embodiments.

FIG. 7 illustrates a cross-sectional view of a photonic system, in accordance with some embodiments.

FIG. 8 illustrates a cross-sectional view of a photonic system, in accordance with some embodiments.

FIG. 9 illustrates a plan view of a photonic system, in accordance with some embodiments.

FIG. 10 illustrates a cross-sectional view of a photonic system, in accordance with some embodiments.

FIG. 11A and 11B illustrate a package component, in accordance with some embodiments.

FIGS. 12, 13, 14, and 15 illustrate intermediate steps in the formation of a photonic interconnect structure, in accordance with some embodiments.

FIG. 16 illustrates a photonic interconnect structure, in accordance with some embodiments.

FIG. 17 illustrates a cross-sectional view of a photonic package, in accordance with some embodiments.

FIG. 18 illustrates a cross-sectional view of a photonic system, in accordance with some embodiments.

FIG. 19 illustrates a plan view of a photonic system, in accordance with some embodiments.

FIG. 20 illustrates a cross-sectional view of a photonic system, in accordance with some embodiments.

FIG. 21 illustrates a cross-sectional view of a photonic package, in accordance with some embodiments.

FIG. 22 illustrates a cross-sectional view of a photonic package, in accordance with some embodiments.

FIG. 23 illustrates a cross-sectional view of a photonic system, in accordance with some embodiments.

FIG. 24 illustrates a cross-sectional view of a photonic system, in accordance with some embodiments.

FIG. 25 illustrates a photonic interconnect structure, in accordance with some embodiments.

FIG. 26 illustrates a cross-sectional view of a photonic system, in accordance with some embodiments.

FIG. 27 illustrates a plan view of a photonic system, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Additionally, arrows are used throughout the figures to indicate the paths of light (e.g., optical signals and/or optical power). It should be understood that for clarity the transmission of light is described along a path in one direction as indicated by arrows, but in some cases, light may also be transmitted in the reverse direction along the path.

Various photonic structures such interposers, packages, and systems and their methods of formation are described herein. A single photonic structure may include multiple device regions for the communication and processing of optical signals. In this manner, device regions of a single photonic structure can facilitate optical communication between multiple components of a package. In some embodiments, within a package, electrical signals may be used for some short-distance communication and optical signals may be used for some long-distance communication.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

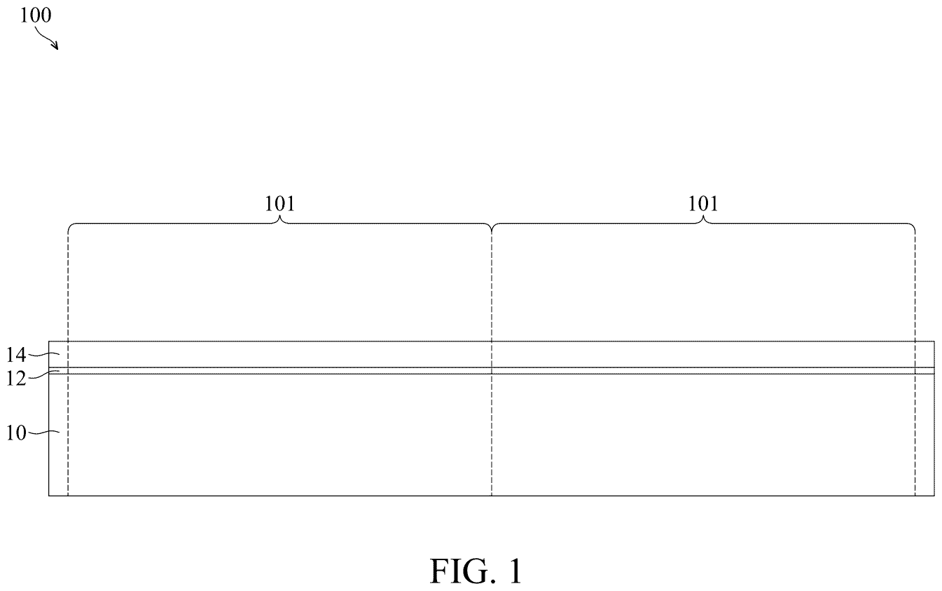

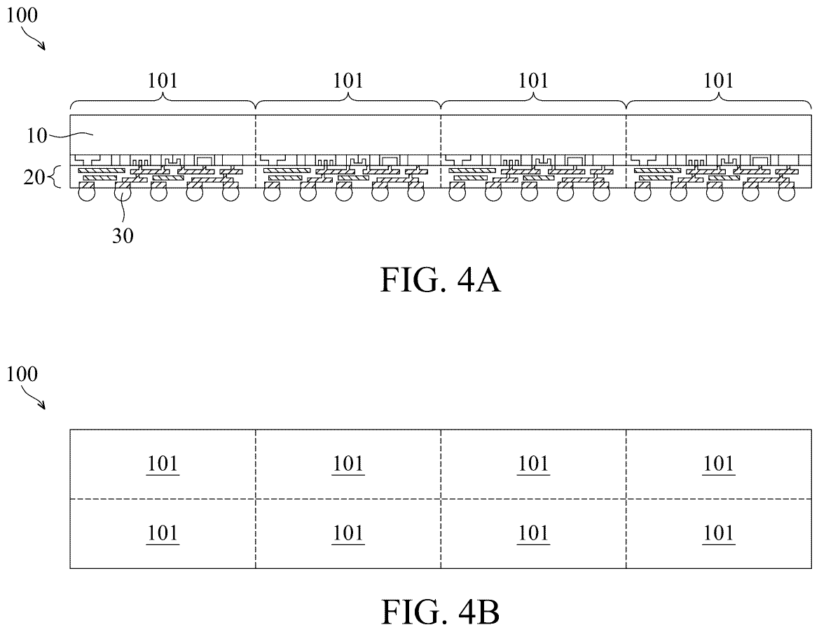

FIGS. 1 through 4B illustrate intermediate steps in the formation of photonic interconnect structure 100 (see FIGS. 4A and 4B), in accordance with some embodiments. The photonic interconnect structure 100 comprises photonic components 18 and/or waveguides 26 that allow for the communication and processing of optical signals throughout the photonic interconnect structure 100. In some embodiments, the photonic interconnect structure 100 comprises multiple device regions 101, each of which may be associated with other package components (e.g., processing dies, memory dies, or the like). The device regions 101 may communicate with each other using optical signals, and thus can facilitate optical communication between the various package components associated with the device regions 101. The device regions 101 may be configured to receive, generate, modify, transmit, and/or process optical signals. By forming multiple device regions 101 in a single photonic interconnect structure 100, manufacturing cost may be reduced, optical loss may be reduced, the efficiency of optical communication within a package may be improved, and/or package size may be reduced. In this manner, the photonic interconnect structure 100 may provide an interface for optical communication in a photonic system. In some cases, the photonic interconnect structure 100 may be considered a photonic integrated circuit (PIC), an optical interposer, or the like.

Turning to FIG. 1, photonic interconnect structure 100 comprises at this stage a first substrate 10, a first insulator layer 12, and photonic layer 14. In an embodiment, at a beginning of the manufacturing process of the photonic interconnect structure 100, the first substrate 10, the first insulator layer 12, and the photonic layer 14 may collectively be part of a silicon-on-insulator (SOI) substrate or the like, which may be doped (e.g., with a p-type or an n-type dopant) or undoped. The first substrate 10 may be a wafer, such as a silicon wafer. Other substrates, such as a silicon-on-insulator (SOI) substrate, a multi-layered substrate, or a gradient substrate may also be used. In some embodiments, the semiconductor material of the first substrate 10 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. In other embodiments, the first substrate 10 may be a dielectric material such as silicon oxide, glass, ceramic, plastic, or any other suitable material that allows for structural support of overlying devices. As indicated in FIG. 1, multiple device regions 101 may be formed on the same first substrate 10. Any suitable number or arrangement of device regions 101 may be formed on the first substrate 10. In some embodiments, multiple photonic interconnect structures 100 may be formed on a single first substrate 10 and then may be subsequently singulated into individual photonic interconnect structures 100. The first substrate 10 may be free of passive or active devices, in some cases.

The first insulator layer 12 may be a dielectric layer that separates the first substrate 10 from the overlying photonic layer 14 and can additionally, in some embodiments, serve as a portion of cladding material that surrounds the subsequently manufactured photonic components 18 (described below). In an embodiment, the first insulator layer 12 may be silicon oxide, silicon nitride, germanium oxide, germanium nitride, combinations of these, or the like. The first insulator layer 12 may be formed using a technique such as implantation (e.g., to form a buried oxide (BOX) layer) or using a suitable deposition technique such as chemical vapor deposition (CVD), atomic layer deposition (ALD), physical vapor deposition (PVD), combinations of these, or the like. However, any suitable material and method of manufacture may be used.

In some embodiments, the photonic layer 14 may be a semiconductor material such as silicon, germanium, silicon germanium, combinations of these, or the like. In other embodiments, the photonic layer 14 may comprise a dielectric material such as silicon nitride or the like, a III-V semiconductor material, lithium niobate materials, polymers, the like, or combinations thereof. The photonic layer 14 may be formed using a suitable technique, such as epitaxial growth, CVD, ALD, PVD, the like, or combinations thereof. Other materials or techniques are possible.

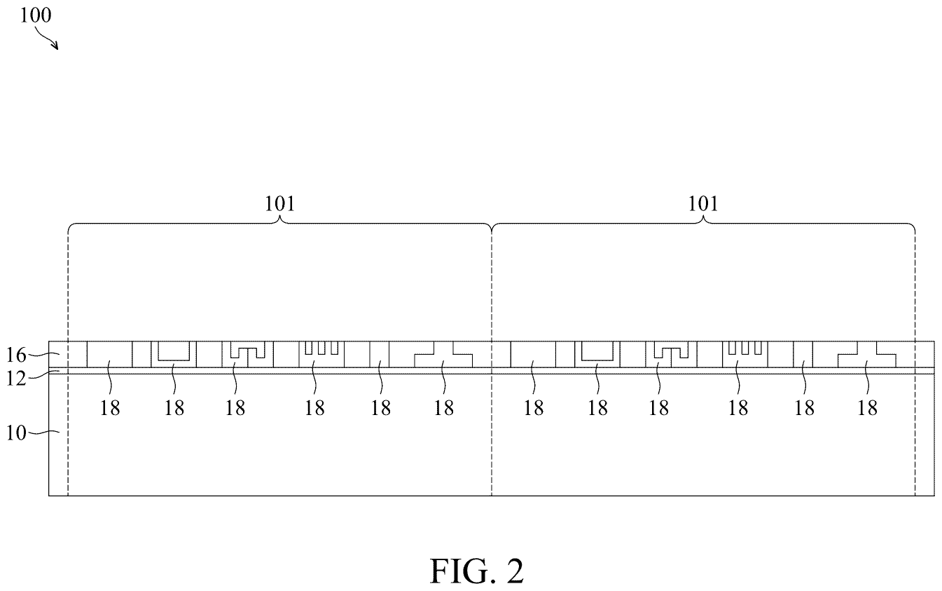

FIG. 2 illustrates the formation of photonic components 18 from the photonic layer 14, in accordance with some embodiments. In some embodiments, the photonic components 18 may include such devices or components as optical waveguides (e.g., ridge waveguides, rib waveguides, buried channel waveguides, diffused waveguides, etc.), couplers (e.g., grating couplers, edge couplers comprising a tip waveguide having a width in the range of about 1 nm to about 200 nm, etc.), directional couplers, optical modulators (e.g., germanium modulators, Mach-Zehnder silicon-photonic switches, microelectromechanical switches, micro-ring resonators, etc.), amplifiers, multiplexors, demultiplexors, optical-to-electrical converters (e.g., photodetectors, P-N junctions, or the like), electrical-to-optical converters, lasers (e.g., laser diodes), phase shifters, combinations of these, or the like. However, the photonic components 18 may comprise other devices structures, or components than these examples.

In some embodiments, the photonic components 18 may be formed by patterning the photonic layer 14 into the appropriate shapes for the photonic components 18. For example, photonic layer 14 may be patterned using one or more photolithographic masking and etching processes, though any suitable method of patterning the photonic layer 14 may be utilized. The patterning may expose portions of the first insulator layer 12. In some cases, additional processing steps may be performed to form some types of photonic components 18, such as additional implantation processes, deposition processes, and/or patterning processes. In some embodiments, one or more photonic components 18 may be formed by patterning the photonic layer 14 and then depositing another material on portions of the patterned photonic layer 14. For example, the formation of a photonic components 18 may comprise patterning a photonic layer 14 comprising silicon and then epitaxially growing a region of germanium on the patterned photonic layer 14, though other materials or process steps are possible.

Sill referring to FIG. 2, a second insulator layer 16 may be formed over the first insulator layer 12 and/or the photonic components 18, in accordance with some embodiments. The second insulator layer 16 may be, for example, a dielectric layer that separates the individual photonic components 18 from each other and from the overlying structures. Further, in some cases, the second insulator layer 16 can additionally serve as a cladding material that at least partially surrounds one or more photonic components 18. In some embodiments, the second insulator layer 16 may comprise silicon oxide, silicon nitride, germanium oxide, germanium nitride, combinations of these, or the like, which may be formed using suitable deposition techniques such as CVD, ALD, PVD, or the like. Other materials or deposition techniques are possible. In some embodiments, after depositing the second insulator layer 16, a planarization process (e.g., a chemical mechanical polishing (CMP) process, a grinding process, or the like) may be performed to planarize a top surface of the second insulator layer 16. In some embodiments, the planarization process may expose a top surface of one or more photonic components 18. In such embodiments, the top surfaces of the photonic components 18 and the top surfaces of the second insulator layer 16 may be level or coplanar (within process variations). In some embodiments, one or more photonic components 18 remain covered by the second insulator layer 16 after performing the planarization process. Each device region 101 may comprise similar photonic components 18 or different photonic components 18.

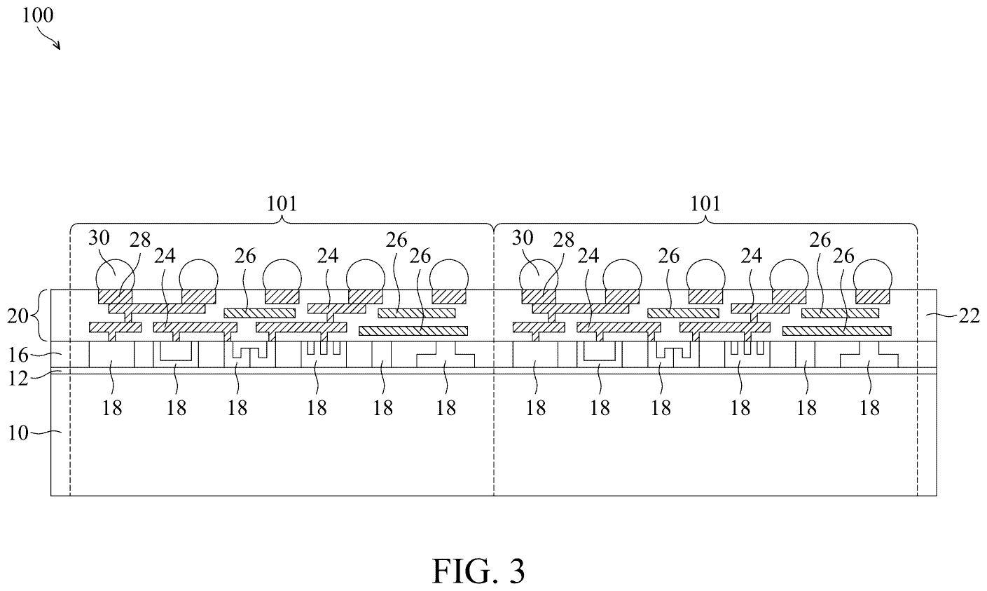

FIG. 3 illustrates the formation of an interconnect structure 20 over the photonic components 18, in accordance with some embodiments. The interconnect structure 20 includes dielectric layers 22 (not individually illustrated) with conductive features 24 and waveguides 26 formed in the dielectric layers 22, in some embodiments. The conductive features 24 allow for electrical communication within the photonic interconnect structure 100 and the waveguides 26 allow for optical communication within the photonic interconnect structure 100.

The conductive features 24 may comprise conductive lines, conductive vias, conductive pads, metallization patterns, redistribution layers, or the like that provide electrical interconnections and electrical routing within the photonic interconnect structure 100. Conductive features 24 may be electrically connected to one or more photonic components 18, in some cases. The interconnect structure 20 may also comprise conductive pads 28 at a top surface of the interconnect structure 20, in some embodiments. The conductive pads 28 may be conductive pads, Under-Bump Metallizations (UBMs), or the like. Conductive connectors 30 may be formed on the conductive pads 28, described in greater detail below.

In some embodiments, the interconnect structure 20 is formed of alternating layers of dielectric material (e.g., dielectric layers 22) and conductive material (e.g., conductive features 24) and/or waveguide material (e.g., waveguides 26). The conductive features 24 may be formed using any suitable processes such as deposition, damascene, dual damascene, or the like. In particular embodiments, the interconnect structure 20 may have multiple layers of conductive features 24, but the precise number of layers of conductive features 24 may be dependent upon the design of the photonic interconnect structure 100. The dielectric layers 22 may be, for example, insulating layers and/or passivating layers, and may comprise silicon oxide, silicon nitride, a polymer, the like, or a combination thereof. The conductive features 24 may include, for example, a metal or a metal alloy such as copper, silver, gold, tungsten, cobalt, ruthenium, aluminum, alloys thereof, combinations thereof, or the like. Other materials are possible.

In some embodiments, the conductive pads 28 are formed in the topmost dielectric layer 22 of the dielectric layers 22. In some embodiments, the conductive pads 28 may include via portions (not illustrated) that physically and electrically contact underlying conductive features 24. The conductive pads 28 may comprise one or more layers of conductive materials such as those described above for the conductive features 24, or the like. In some embodiments, the conductive pads 28 are UBMs, which may include portions on and extending along the major surface of the topmost dielectric layer 22. Other types of conductive pads 28 are possible.

As mentioned above, the interconnect structure 20 may include one or more layers of waveguides 26 within the dielectric layers 22. In some embodiments, photonic components may also be formed in the interconnect structure 20, which may be similar to the photonic components 18 described previously. In some cases, the waveguides 26 may be optically coupled to each other and/or to one or more photonic components 18. In some embodiments, waveguides 26 may be formed during the manufacture of the interconnect structure 20 by depositing a waveguide material on a dielectric layer 22. The waveguide material may be a dielectric material such as silicon nitride, silicon oxide, silicon oxynitride, polymer, combinations of these, or the like, or a semiconductor material such as silicon, germanium, or the like. The waveguide material may be deposited using a suitable technique, such as ALD, PVD, or the like. The waveguide material may then be patterned using suitable photolithography and etching techniques to form a layer of waveguides 26. Another dielectric layer 22 may then be deposited on the waveguides 26. In particular embodiments, the interconnect structure 20 may have multiple layers of waveguides 26, but the precise number of layers of waveguides 26 may be dependent upon the design of the photonic interconnect structure 100.

Still referring to FIG. 3, conductive connectors 30 may be formed on the conductive pads 28, in accordance with some embodiments. The conductive connectors 30 may be, for example, ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 30 may include a conductive material such as solder, copper, aluminum, gold, nickel, silver, palladium, tin, the like, or a combination thereof. In some embodiments, the conductive connectors 30 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 30 comprise metal pillars (such as a copper pillar) formed by a sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process. In other embodiments, the conductive connectors 30 are omitted and the conductive pads 28 are bonding pads used for metal-to-metal bonding to an external component.

A photonic interconnect structure 100 may have any suitable dimensions and any suitable number and/or arrangement of device regions 101. As another example, FIG. 4A illustrates a cross-sectional view of a photonic interconnect structure 100 and FIG. 4B illustrates a plan view of a photonic interconnect structure 100, in accordance with some embodiments. The photonic interconnect structure 100 of FIGS. 4A-4B may be similar to the photonic interconnect structure 100 of FIG. 3, except for the number and arrangement of device regions 101. In some cases, FIG. 3 may be considered a magnified view of the photonic interconnect structure 100 shown in FIG. 4A. In some embodiments, a photonic interconnect structure 100 may have a length in the range of about 3000 μm to about 300000 μm or a width in the range of about 500 μm to about 100000 μm, though other dimensions are possible.

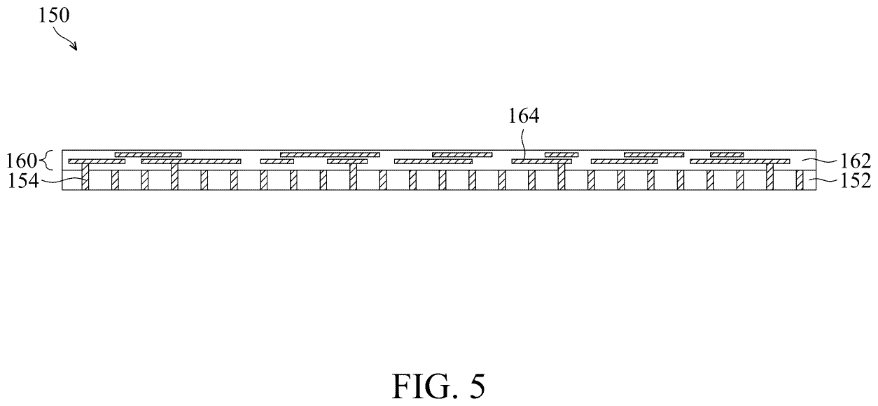

FIG. 5 illustrates a cross-sectional view of an interposer 150, in accordance with some embodiments. The interposer 150 comprises a substrate 152, an interconnect structure 160 on the substrate 152, and through vias 154, in accordance with some embodiments. The substrate 152 may be a semiconductor substrate (e.g., a silicon wafer) or another type of substrate, such as those described previously for the first substrate 10.

The interconnect structure 160 comprises one or more layers of conductive features 164 formed in one or more dielectric layers 162 (not individually illustrated). The conductive features 164 may include conductive lines, conductive vias, conductive pads, or the like, which may be formed using any suitable technique such as damascene, dual damascene, or the like. For example, the conductive features 164 may be formed using techniques similar to those described previously for the conductive features 24. In other embodiments, the interconnect structure 160 comprises one or more waveguides formed in the dielectric layers 162.

The through vias 154 of the interposer 150 extend through the substrate 152 and are electrically connected to the interconnect structure 160. The through vias 154 may be formed, for example, by forming openings extending through the substrate 152 and one or more dielectric layers 162 to expose surfaces of the conductive features 164. The openings may be formed using acceptable photolithography and etching techniques, such as by forming and patterning a photoresist and then performing an etching process using the patterned photoresist as an etching mask. The etching process may include, for example, a dry etching process and/or a wet etching process. A conductive material may then be formed in the openings, thereby forming the through vias 154. In some embodiments, a liner (not shown) may be deposited in the openings prior to forming the conductive material. The conductive material may comprise, for example, a metal or a metal alloy such as copper, silver, gold, tungsten, cobalt, aluminum, alloys thereof, or the like. A planarization process (e.g., a CMP process or a grinding process) may be performed to remove excess conductive material along the surface of the interposer 150 (e.g., the substrate 152) such that surfaces of the through vias 154 and the interposer 150 are level. In other embodiments, the through vias 154 extend fully through the interposer 150. Other materials or techniques are possible. In other embodiments, the through vias 154 are omitted.

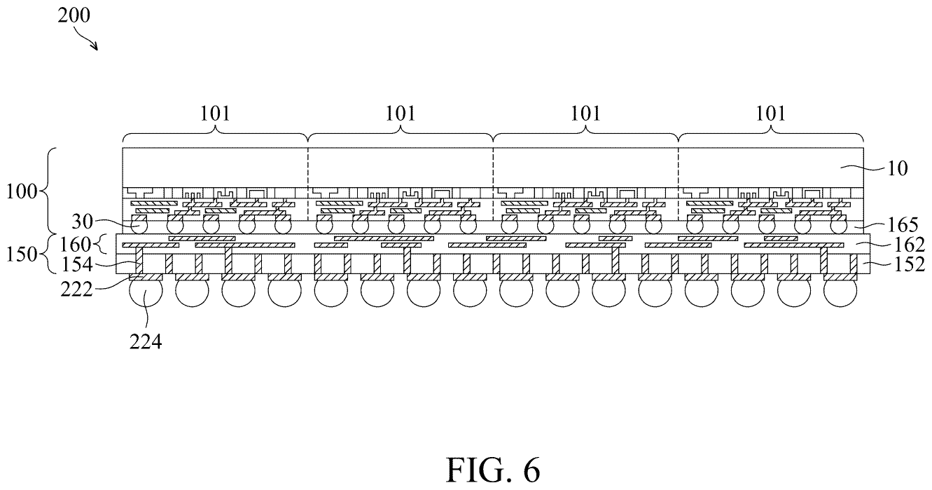

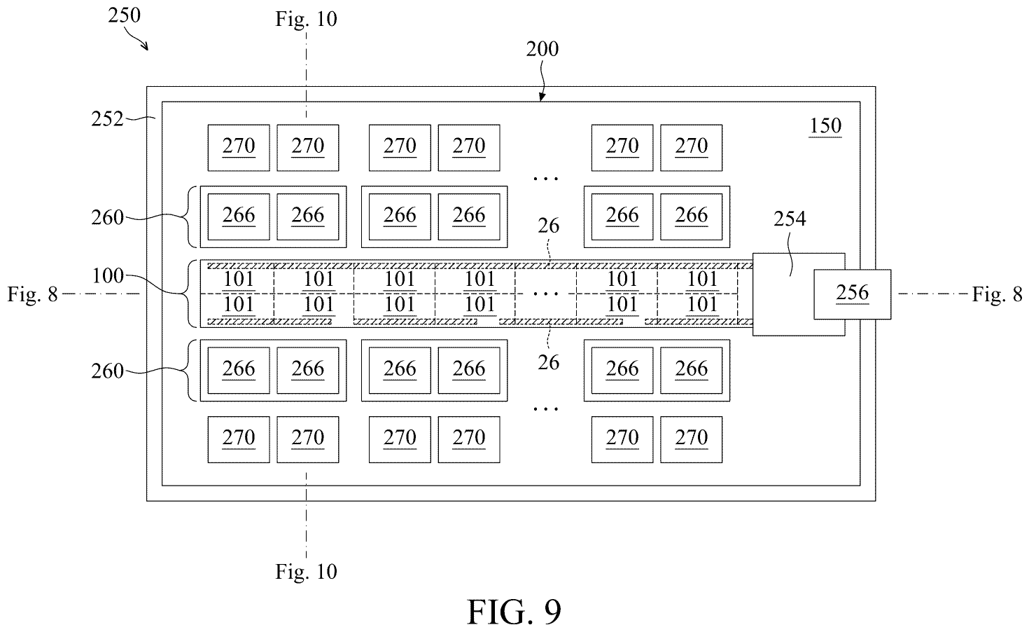

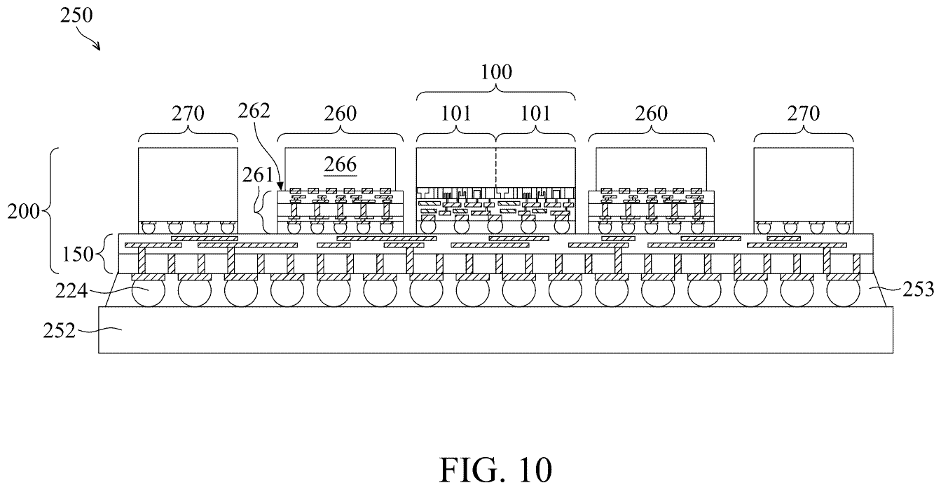

In FIG. 6, the photonic interconnect structure 100 is connected to the interposer 150 to form a photonic package 200, in accordance with some embodiments. Other package components (e.g., package components 260 or devices 270 of FIGS. 9-10) may also be connected to the interposer 150, described in greater detail below. In some embodiments, the conductive connectors 30 of the photonic interconnect structure 100 may be placed on corresponding conductive pads (not separately illustrated) of the interposer 150. The conductive pads may be formed in or on a top dielectric layer 162 of the interposer 150. For example, the conductive pads may be similar to conductive pads 28 described for the photonic interconnect structure 100, though other conductive pads are possible. A reflow process may then be performed to bond the conductive connectors 30 to the interposer 150. In this manner, the photonic interconnect structure 100 is physically and electrically connected to the interposer 150, and the interposer 150 may provide electrical interconnections between the photonic interconnect structure 100 and other package components. The interposer 150 may also provide electrical interconnections between device regions 101 of the photonic interconnect structure 100, in some embodiments. In some embodiments, an underfill 165 may be deposited between the photonic interconnect structure 100 and the interposer 150. In some embodiments, sidewalls of the photonic interconnect structure 100 are offset from sidewalls of the interposer 150, as shown in FIG. 6. In other embodiments, sidewalls of the photonic interconnect structure 100 and the interposer 150 may be substantially coplanar.

Further in FIG. 6, conductive pads 222 and/or conductive connectors 224 may be formed on the interposer 150, in accordance with some embodiments. The conductive pads 222 may be formed on the substrate 152 of the interposer 150, and may be electrically connected to through vias 154. The conductive pads 222 may be similar to the conductive pads 28 described previously, though other types, materials, or formation processes of conductive pads 222 are possible. Conductive connectors 224 may then be formed on the conductive pads 222, in accordance with some embodiments. The conductive connectors 224 may be similar to the conductive connectors 30 described previously, though other conductive connectors 224 are possible. In other embodiments, a second interconnect structure (not illustrated) is formed on the substrate 152 opposite the interconnect structure 160, and conductive connectors 224 are formed on the second interconnect structure.

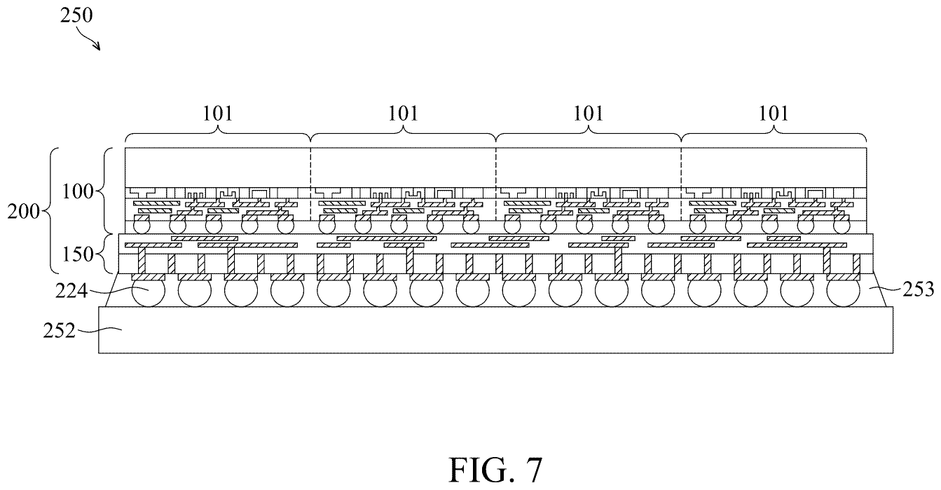

FIG. 7 illustrates the connection of a photonic package 200 to a package substrate 252 to form a photonic system 250, in accordance with some embodiments. The package substrate 252 may comprise conductive pads, conductive routing, and/or other conductive features that provide interconnections and electrical routing. In some embodiments, the package substrate 252 may comprise an interposer, a semiconductor substrate (e.g., a wafer), a redistribution structure, an interconnect substrate, a core substrate, a printed circuit board (PCB), or the like. In some embodiments, the package substrate 252 comprises active and/or passive devices. In other embodiments, the package substrate 252 is free of active and/or passive devices.

In some embodiments, the conductive connectors 224 of the photonic package 200 are placed on corresponding conductive pads (not separately illustrated) of the package substrate 252 and then a reflow process is performed to bond the photonic package 200 to the package substrate 252. In this manner, the photonic package 200 may be physically and electrically connected to the package substrate 252. In other embodiments, the photonic package 200 may be bonded to the package substrate 252 using dielectric-to-dielectric bonding and/or metal-to-metal bonding (e.g., direct bonding, fusion bonding, oxide-to-oxide bonding, hybrid bonding, or the like). In some embodiments, an underfill 253 may be deposited between the photonic package 200 and the package substrate 252.

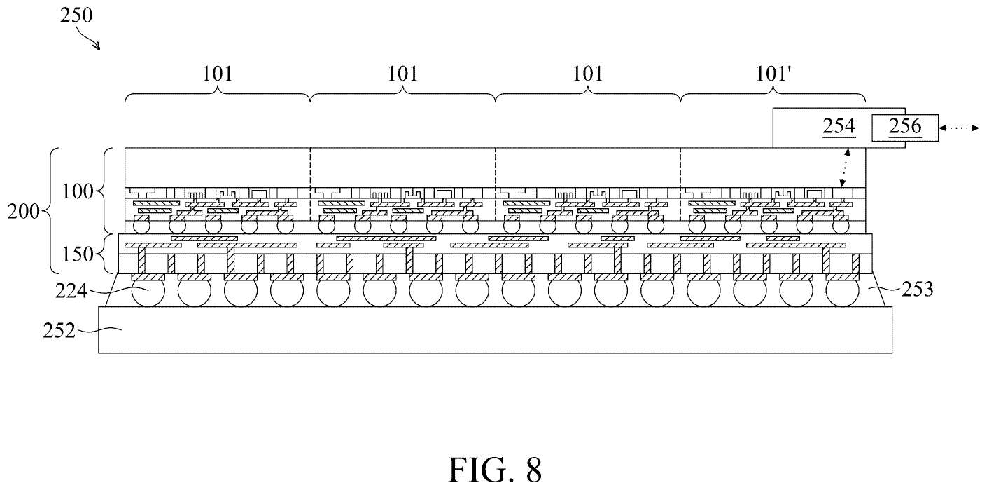

FIG. 8 illustrates a photonic system 250 with a fiber coupler 254, in accordance with some embodiments. The photonic system 250 of FIG. 8 is similar to the photonic system 250 of FIG. 7, except that a fiber coupler 254 is attached to a device region 101′ of the photonic package 200. The fiber coupler 254 may facilitate communication between the photonic system 250 and an optical fiber 256. In this manner, the fiber coupler 254 may facilitate optical communication between the photonic system 250 and external photonic systems, packages, or components. The optical fiber 256 may comprise one or more optical fibers, which may be an array or the like. The fiber coupler 254 may be a fiber array unit (FAU) or the like that is configured to couple optical signals from the photonic package 200 into the optical fiber 256 and/or couple optical signals from the optical fiber 256 into the photonic package 200. For example, the fiber coupler 254 may be optically coupled to waveguides 26 within the device region 101′. Accordingly, the device region 101′ may be configured to optically communicate with the fiber coupler 254. For example, the fiber coupler 254 may be coupled to the waveguides 26 through the first substrate 10 and may couple optical signals to the waveguides 26 using reflectors, grating couplers, lenses, or the like. In some embodiments, the photonic system 250 receives optical power provided by the optical fiber 256 through the fiber coupler 254. In other embodiments, the fiber coupler 254 is not present or multiple fiber couplers 254 may be used.

FIG. 9 illustrates a plan view of a photonic system 250, in accordance with some embodiments. The photonic system 250 of FIG. 9 may be similar to the photonic system 250 of FIG. 8, and a cross-section similar to the cross-sectional view of FIG. 8 is indicated in FIG. 9. FIG. 10 illustrates a cross-sectional view of a photonic system 250 similar to that of FIGS. 8-9, and a cross-section similar to the cross-sectional view of FIG. 10 is indicated in FIG. 9. The photonic system 250 comprises a photonic package 200 connected to a package substrate 252. The photonic package 200 comprises a photonic interconnect structure 100, package components 260, and devices 270 connected to an interposer 150. The photonic system 250 shown in FIGS. 9-10 is intended as an illustrative example, and other structures having other configurations, arrangements, dimensions, or features are possible. For clarity, some features are not shown in FIG. 9, such as conductive features 164 of the interposer 150, some waveguides 26 of the photonic interconnect structure 100, or the like.

The package components 260 and/or the devices 270 may include, for example, a chip, a die, a system-on-chip (SoC) device, a system-on-integrated-circuit (SoIC) device, a package, the like, or a combination thereof. In some embodiments, the package components 260 and/or the devices 270 comprise logic dies, memory dies, input-output (I/O) dies, Integrated Passive Devices (IPDs), or the like, or combinations thereof. For example, the package components 260 and/or the devices 270 may comprise logic dies such as Central Processing Unit (xPU or CPU) dies, Graphic Processing Unit (GPU) dies, mobile application dies, Micro Control Unit (MCU) dies, BaseBand (BB) dies, Application processor (AP) dies, Application-Specific Integrated Circuit (ASIC) dies, or the like. The package components 260 and/or the devices 270 may comprise memory dies such as Static Random-Access Memory (SRAM) dies, Dynamic Random-Access Memory (DRAM) dies, High-Bandwidth Memory (HBM) dies, or the like. In some embodiments, the package components 260 and/or the devices 270 are connected to the interposer 150 by conductive connectors, which may be similar to the conductive connectors 30 of the photonic interconnect structure 100, in some cases. For example, the conductive connectors may comprise ball grid array (BGA) connectors, solder balls, metal pillars, controlled collapse chip connection (C4) bumps, micro bumps, electroless nickel-electroless palladium-immersion gold technique (ENEPIG) formed bumps, or the like. In other embodiments, different numbers or other types of package components 260 and/or devices 270 may be connected to the interposer 150.

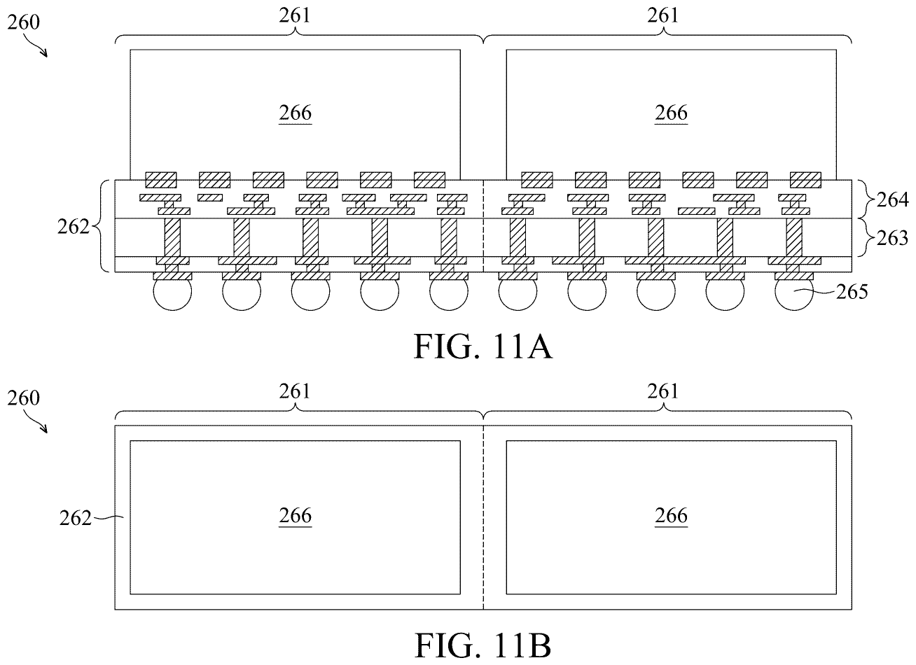

In some embodiments, the package components 260 may act as part of an I/O interface between optical signals and electrical signals within a photonic package 200. As an illustrative example, FIGS. 11A and 11B illustrate a cross-sectional view and a plan view of a package component 260, in accordance with some embodiments. In the embodiment shown in FIGS. 9-10 and 11A-11B, the package component 260 is a structure comprising one more dies 266 connected to an active interposer 262. The package component 260 could be considered a system-on-chip (SoC) device or a system-on-integrated-circuit (SoIC) device, in some cases. In other embodiments, a package component 260 may have a different configuration, may include another number of die(s) 266, or may be another type of die, chip, package, or the like.

Still referring to FIGS. 11A-11B, the active interposer 262 may comprise a substrate 263 and an interconnect structure 264 formed on one side of the substrate 263. The substrate 263 may be similar to those described previously for the first substrate 10, such as a silicon wafer or the like. In some embodiments, integrated circuits (not separately illustrated) may be formed in the substrate 263 using suitable techniques. For example, the integrated circuits may include controllers, drivers, transimpedance amplifiers, transistors, other active devices, passive devices, the like, or combinations thereof. In some embodiments, the integrated circuits may be configured to interface with the photonic interconnect structure 100. For example, the integrated circuits may be configured to control the operation of the photonic components 18, to process electronic signals received from the photonic interconnect structure 100 that correspond to optical signals, or the like. In some embodiments, the active interposer 262 includes circuits for processing electrical signals received from the photonic interconnect structure 100, such as for processing electrical signals received from a photonic component 18 comprising a photodetector. The active interposer 262 may control high-frequency signaling of the photonic components 18 according to electrical signals (digital or analog) received from another device or die (e.g. a die 266, described below), in some embodiments. In some embodiments, the active interposer 262 may provide Serializer/Deserializer (SerDes) functionality. In this manner, the active interposer 262 may be considered an Electronic Integrated Circuit (EIC) die, in some cases. The active interposer 262 is electrically connected to the photonic interconnect structure 100 (and any corresponding devices 270) through the interposer 262.

In some embodiments, the active interposer 262 comprises through vias that extend through the substrate 263, which may be electrically connected to the interconnect structure 264. The interconnect structure 264 may comprise, for example, conductive lines, conductive vias, and/or conductive pads formed in dielectric layers to provide electrical interconnections. In some cases, the interconnect structure 264 may be similar to the interconnect structure 160 of the interposer 150, and may be formed using similar materials or techniques. In some embodiments, another interconnect structure may be formed on the substrate 263 opposite the interconnect structure 264, which the through vias may also electrically connect. Conductive connectors 265 may be formed on the active interposer 262, which may be similar to the conductive connectors 30 described previously.

One or more dies 266 may be connected to the interconnect structure 264 of the active interposer 262, in some embodiments. A die 266 may include one or more processing devices, such as a central processing unit (CPU or “xPU”), a graphics processing unit (GPU), an application-specific integrated circuit (ASIC), a high performance computing (HPC) die, a logic die, dies similar to those previously mentioned above, the like, or a combination thereof. A die 266 may include one or more memory devices, which may be a volatile memory such as dynamic random-access memory (DRAM), static random-access memory (SRAM), high-bandwidth memory (HBM), another type of memory, or the like.

In some embodiments, the dies 266 may include bond pads formed in a bonding layer, and the dies 266 are bonded to the active interposer 262 by dielectric-to-dielectric bonding and/or metal-to-metal bonding (e.g., direct bonding, fusion bonding, oxide-to-oxide bonding, hybrid bonding, or the like). In some embodiments, the bonding layer of a die 266 is bonded to a bonding layer (e.g., the topmost dielectric layer) of the interconnect structure 264 using a dielectric-to-dielectric bonding process, and bond pads of the die 266 are bonded to corresponding conductive pads of the interconnect structure 264 using a metal-to-metal bonding process. In some embodiments, the bonding process may be initiated by activating the bonding surfaces of the bonding layers of the die 266 and the interconnect structure 264, which can facilitate bonding of the bonding surfaces. Activating the bonding surfaces may comprise, for example, a dry treatment, a wet treatment, a plasma treatment, exposure to an inert gas plasma, exposure to H₂, exposure to N₂, exposure to O₂, combinations thereof, or the like. For embodiments in which a wet treatment is used, an RCA cleaning process may be used, for example. In other embodiments, the activation process may comprise other types of treatments. After the activation process, the die 266 is aligned and placed into physical contact with the interconnect structure 264. The die 266 and the active interposer 262 are then subjected to a thermal treatment and contact pressure to bond the bonding layers with dielectric-to-dielectric bonding and bond the bond pads of the die 266 to the conductive pads of the interconnect structure 264 with metal-to-metal bonding. In some embodiments, the bonded structure is subsequently baked, annealed, pressed, or otherwise treated to strengthen or finalize the bond. This is an example, and other bonding processes are possible. In other embodiments, the dies 266 may comprise conductive connectors (e.g. solder bumps or the like), and may be bonded to the active interposer 262 using these conductive connectors.

In some embodiments, the package component 260 has multiple device regions 261, each of which may be associated with a corresponding device region 101 of the photonic interconnect structure 100. For example, the package component 260 shown in FIGS. 11A-11B has two device regions 261, though another number of device regions 261 is possible. In some embodiments, each device region 261 comprises a portion of the active interposer 262 and a die 266. In this manner, the combination of a device region 261 and a device region 101 may provide optical signal processing, interfacing, and/or communication for a photonic system 250. In some embodiments, a device region 261 and/or a device region 101 may each have one or more associated devices 270. For example, the devices 270 may be memory dies such as HBM dies or the like, though other devices 270 are possible. Other associations, arrangements, or configurations are possible.

In this manner, the photonic interconnect structure 100, the package components 260, and the devices 270 of the photonic package 200 are electrically connected by conductive features 164 within the interposer 150. The conductive features 164 may enable relatively short-distance communications within the photonic package 200 using electrical signals. In some embodiments, waveguides 26 within the photonic interconnect structure 100 are utilized to transmit optical signals within the photonic package 200, such as optical signals transmitted between device regions 101. In this manner, the waveguides 26 may be used to provide relatively long-distance communications within the photonic package 200 using optical signals. As an example, a die 266 of a first package component 260 may transmit electrical signals to the associated active interposer 262, which then transmits corresponding electrical signals to photonic components 18 of a first device region 101 of the photonic interconnect structure 100 to generate optical signals. The optical signals are transmitted within the photonic interconnect structure 100 by waveguides 26 to a second device region 101, where they may be received by other photonic components 18 within the second device region 101. The photonic components 18 of the second device region 101 send corresponding electrical signals to a corresponding second package component 260. The active interposer 262 of the second package component 260 receives the electrical signals and transmits corresponding electrical signals to a die 266 of the second package component 260. This is an example, and other processes are possible. In this manner, by using electrical signals over short distances through the interposer 150 and optical signals over long distances through the photonic interconnect structure 100, the efficiency, speed, and/or bandwidth of a photonic package 200 (or a photonic system 250) may be improved, and manufacturing cost may be reduced.

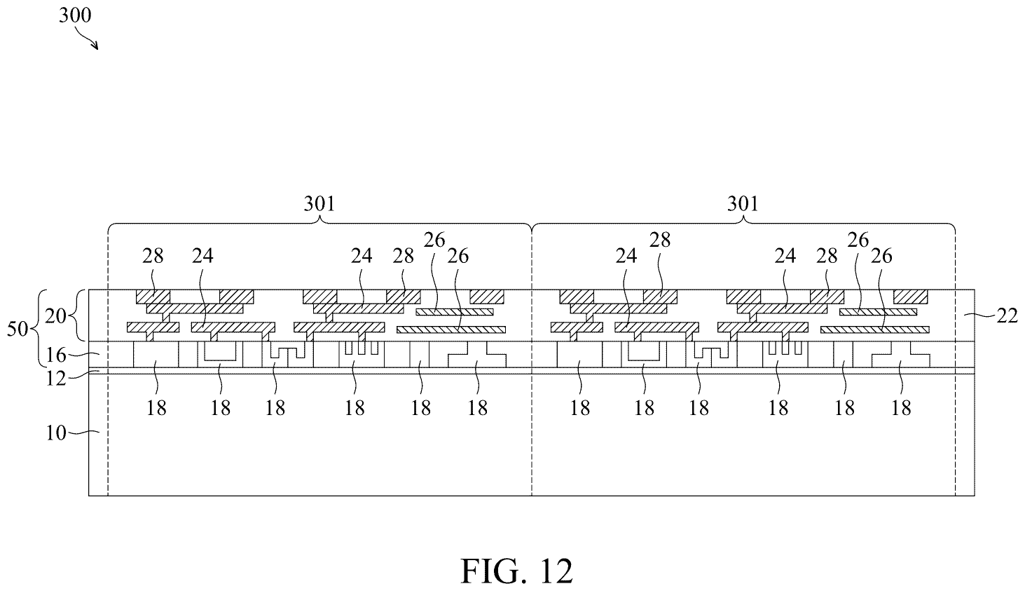

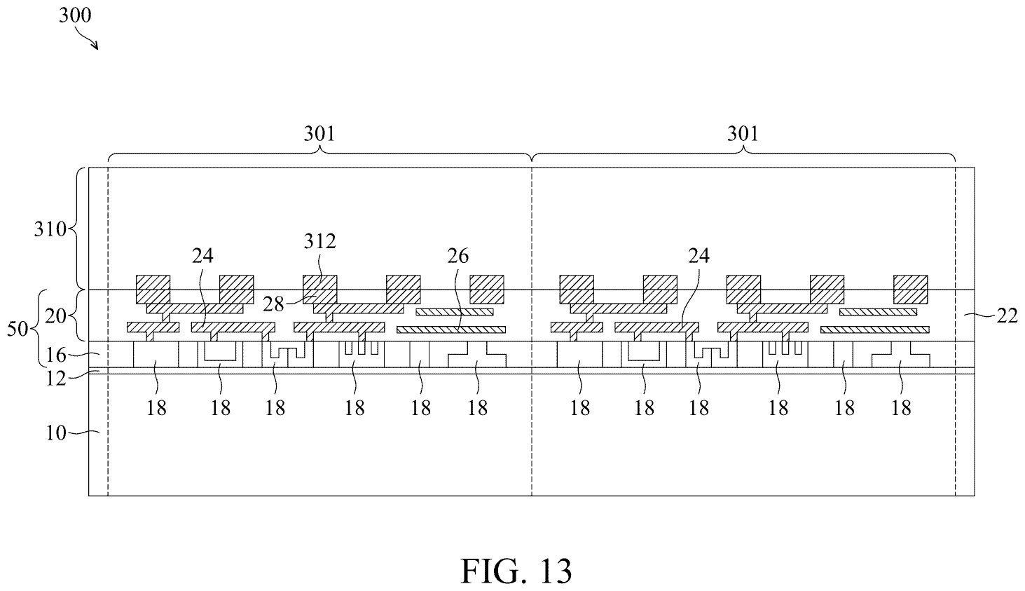

FIGS. 12 through 15 illustrate intermediate steps in the formation of a photonic interconnect structure 300, in accordance with some embodiments. The photonic interconnect structure 300 is similar to the photonic interconnect structure 100 described previously, except that the photonic interconnect structure 300 comprises an electronic die 310 (see FIG. 13). In some embodiments, the electronic die 310 may provide functionality similar to that described previously for the active interposer 262. In this manner, a photonic interconnect structure 300 may provide both optical signal communication and optical signal processing, which can improve efficiency and reduce manufacturing cost. Some features or processing steps of the photonic interconnect structure 300 may be similar to those previously described for the photonic interconnect structure 100. Accordingly, some similar features may have similar reference numerals, and some similar details may not be repeated. In some embodiments, the photonic interconnect structure 300 comprises multiple device regions 301 that may be associated with other package components or dies of a photonic package, similar to the device regions 101 described previously.

FIG. 12 illustrates a structure similar to the photonic interconnect structure 100 illustrated previously in FIG. 3, except that conductive connectors 30 are not present. For example, the structure shown in FIG. 12 includes an optical interposer 50 formed over a first substrate 10. The optical interposer 50 comprises, for example, photonic components 18 and an interconnect structure 20 formed over the photonic components 18 that comprises conductive features 24 and waveguides 26 formed in dielectric layers 22. In other embodiments, waveguides 26 are not formed in the interconnect structure 20. The structure shown in FIG. 12 may be formed using materials or techniques similar to those described previously for the photonic interconnect structure 100, such as those described for FIGS. 1-3. In some embodiments, the conductive pads 28 may be bond pads suitable for metal-to-metal bonding, and may comprise correspondingly suitable materials such as copper, a copper alloy, or the like. In some embodiments, the topmost dielectric layer 22 may comprise a material suitable for dielectric-to-dielectric bonding, such as silicon oxide or the like, and may be considered a “bonding layer.” A planarization process (e.g., a CMP process or grinding process) may be performed such that the conductive pads 28 and the topmost dielectric layer 22 have level or coplanar surfaces.

In FIG. 13, an electronic die 310 is bonded to the interconnect structure 20, in accordance with some embodiments. In some cases, the electronic die may be considered an Electronic Integrated Circuit (EIC) die or the like. In some embodiments, the electronic die 310 may comprise device regions that correspond to device regions of the underlying structure and which correspond to device regions 301 of the final photonic interconnect structure 300. In some embodiments, the electronic die 310 may include bond pads 312 formed in a bonding layer, and the electronic die 310 is bonded to the interconnect structure 20 by dielectric-to-dielectric bonding and/or metal-to-metal bonding (e.g., direct bonding, fusion bonding, oxide-to-oxide bonding, hybrid bonding, or the like), described in greater detail below.

After bonding, the electronic die 310 may be electrically connected to the photonic components 18 through the interconnect structure 20. The electronic die 310 may include integrated circuits for interfacing with the photonic components 18, such as circuits for controlling the operation of the photonic components 18. For example, the electronic die 310 may include controllers, drivers, transimpedance amplifiers, the like, or combinations thereof. The electronic die 310 may include, for example, a chip, a die, a system-on-chip (SoC) device, a system-on-integrated-circuit (SoIC) device, a package, the like, or a combination thereof. The electronic die 310 may include one or more processing devices, such as a central processing unit (CPU or “xPU”), a graphics processing unit (GPU), an application-specific integrated circuit (ASIC), a high performance computing (HPC) die, a logic die, the like, or a combination thereof. The electronic die 310 may include one or more memory devices, which may be a volatile memory such as dynamic random-access memory (DRAM), static random-access memory (SRAM), high-bandwidth memory (HBM), another type of memory, or the like. In some embodiments, the electronic die 310 includes circuits for processing electrical signals received from photonic components 18, such as for processing electrical signals received from a photonic component 18 comprising a photodetector. The electronic die 310 may control high-frequency signaling of the photonic components 18 according to electrical signals (digital or analog) received from another device or die, in some embodiments. In some embodiments, the electronic die 310 may provide Serializer/Deserializer (SerDes) functionality. In some embodiments, the electronic die 310 may act as part of an I/O interface between optical signals and electrical signals within a photonic interconnect structure 300. In some cases, the photonic interconnect structure 300 described herein could be considered a system-on-chip (SoC) device, a system-on-integrated-circuit (SoIC) device, an “optical engine”, an “optical die,” an “optical structure,” or the like.

In some embodiments, the bonding layer of the electronic die 310 is bonded to the topmost dielectric layer 22 (e.g., the “bonding layer”) of the interconnect structure 20 using a dielectric-to-dielectric bonding process, and the bond pads 312 of the electronic die 310 are bonded to corresponding conductive pads 28 of the interconnect structure 20 using a metal-to-metal bonding process. In some embodiments, the bonding process may be initiated by activating the bonding surfaces of the bonding layers, which can facilitate bonding of the bonding surfaces. Activating the bonding surfaces may comprise, for example, a dry treatment, a wet treatment, a plasma treatment, exposure to an inert gas plasma, exposure to H₂, exposure to N₂, exposure to O₂, combinations thereof, or the like. For embodiments in which a wet treatment is used, an RCA cleaning process may be used, for example. In other embodiments, the activation process may comprise other types of treatments.

After the activation process, the interconnect structure 20 and the electronic die 310 may be cleaned using, e.g., a chemical rinse or the like, and then the electronic die 310 is aligned and placed into physical contact with the interconnect structure 20. A thermal treatment and contact pressure may then be used to bond the bonding layers together with dielectric-to-dielectric bonding and bond the bond pads 312 to the conductive pads 28 with metal-to-metal bonding. In some embodiments, the bonded structure is subsequently baked, annealed, pressed, or otherwise treated to strengthen or finalize the bond. This is an example, and other bonding processes are possible. In some embodiments, a planarization process is performed to remove portions of the electronic die 310. In some embodiments, a support structure (not illustrated) is attached to the electronic die 310 to provide mechanical support for the photonic interconnect structure 300.

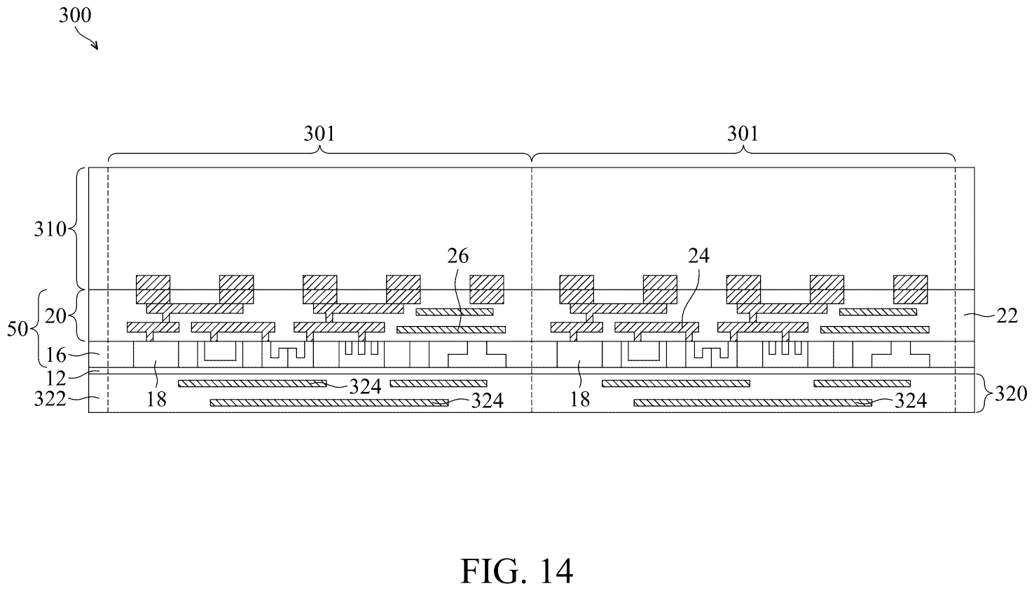

In FIG. 14, the first substrate 10 is removed and an optical interconnect structure 320 is formed on the optical interposer 50, in accordance with some embodiments. In some embodiments, the first substrate 10 is removed using a planarization process, such as a CMP process, a grinding process, one or more etching processes, combinations of these, or the like. In other embodiments, the first insulator layer 12 is also removed. The optical interconnect structure 320 comprises waveguides 324 formed within one or more dielectric layers 322 (not individually illustrated), in accordance with some embodiments. The waveguides 324 may be similar to the waveguides 26 described previously. For example, in some embodiments, the waveguides 324 may comprise silicon nitride waveguides, couplers, or the like. In some cases, one or more waveguides 324 may be optically coupled to each other and/or to one or more photonic components 18. In this manner, the optical interconnect structure 320 may provide optical communication and optical interconnection within a photonic interconnect structure 300. In other embodiments, conductive features are also formed in the optical interconnect structure 320.

The waveguides 324 may be formed using materials or techniques similar to those used to form the waveguides 26, in some embodiments. For example, the waveguides 324 may be formed by depositing a material for waveguides 324 on a dielectric layer 322 and then patterning the material using suitable photolithography and etching techniques. The material for the waveguides 324 may be a dielectric material such as silicon nitride, silicon oxide, silicon oxynitride, polymer, combinations of these, or the like. Another dielectric layer 322 may then be deposited on the waveguides 324. The dielectric layers 322 may comprise, for example, silicon oxide, spin-on glass, or the like. Other materials are possible. In particular embodiments, the optical interconnect structure 320 may have multiple layers of waveguides 324, but the precise number of layers of waveguides 324 and/or dielectric layers 322 may be dependent upon the design of the photonic interconnect structure 300.

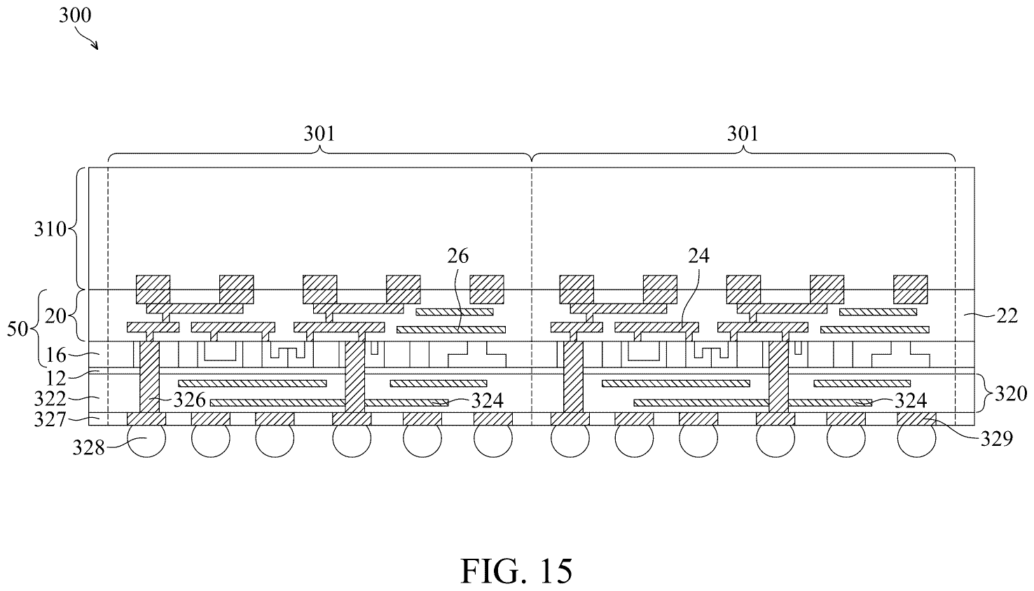

In FIG. 15, vias 326 are formed extending through the optical interconnect structure 320 and the second insulator layer 16, in accordance with some embodiments. The vias 326 may physically and electrically contact conductive features 24 of the interconnect structure 20. In some embodiments, the vias 326 may extend into one or more of the dielectric layers 22. The vias 326 may be formed, for example, by forming openings extending through the dielectric layers 322, the second insulator layer 16, and/or one or more dielectric layers 22 to expose surfaces of the conductive features 24. The openings may be formed using acceptable photolithography and etching techniques, such as by forming and patterning a photoresist and then performing an etching process using the patterned photoresist as an etching mask. The etching process may include, for example, a dry etching process and/or a wet etching process. A conductive material may then be formed in the openings, thereby forming the vias 326. In some embodiments, a liner (not shown) may be deposited in the openings prior to forming the conductive material. The conductive material may comprise, for example, a metal or a metal alloy such as copper, silver, gold, tungsten, cobalt, aluminum, alloys thereof, or the like. A planarization process (e.g., a CMP process or a grinding process) may be performed to remove excess conductive material along the surface of the optical interconnect structure 320 (e.g., the dielectric layers 322), such that surfaces of the vias 326 and the optical interconnect structure 320 are level. Other materials or techniques are possible. In other embodiments, the vias 326 are omitted.

Still referring to FIG. 15, a passivation layer 327 may be formed over the optical interconnect structure 320, in accordance with some embodiments. The passivation layer 327 may comprise, for example, a polymer such as PBO, polyimide, BCB, or the like; a nitride such as silicon nitride or the like; an oxide such as silicon oxide, PSG, BSG, BPSG, or the like; an encapsulant, molding compound, or the like; the like, or a combination thereof. The passivation layer 327 may be formed, for example, by spin coating, lamination, CVD, PVD, ALD, or the like. In some embodiments, photonic components such as waveguides or the like may also be formed in the passivation layer 327.

Under-bump metallizations (UBMs) 329 may then be formed within the passivation layer 327 to make physical and electrical contact to the vias 326. In other embodiments, the UBMs 329 are formed prior to forming the passivation layer 327. In such embodiments, openings are formed in the passivation layer 327 that may expose the UBMs 329. In some embodiments, the UBMs 329 may be formed by forming openings in the passivation layer 327 using acceptable photolithography and etching techniques, such as by forming and patterning a photoresist and then performing an etching process using the patterned photoresist as an etching mask. The etching process may include, for example, a dry etching process and/or a wet etching process. One or more conductive materials may then be deposited in the openings, forming the UBMs 329. In other embodiments, the UBMs 329 have bump portions on and extending along the major surface of the passivation layer 327. In other embodiments, the passivation layer 327 and/or the UBMs 329 are not formed. Conductive connectors 328 may then be formed on the UBMs 329, in accordance with some embodiments. The conductive connectors 328 may be similar to the conductive connectors 30 or 265 described previously. For example, the conductive connectors 328 may be solder bumps or the like in some embodiments.

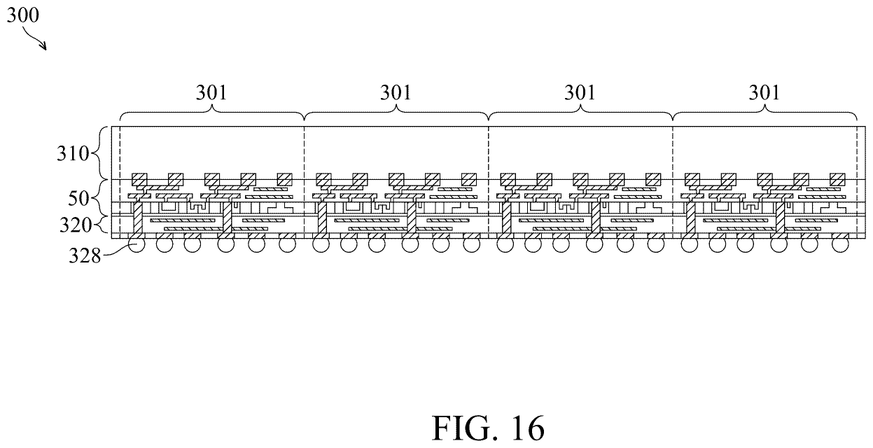

A photonic interconnect structure 300 may have any suitable dimensions and any suitable number and/or arrangement of device regions 301. As another example, FIG. 16 illustrates a cross-sectional view of a photonic interconnect structure 300, in accordance with some embodiments. The photonic interconnect structure 300 of FIG. 16 may be similar to the photonic interconnect structure 300 of FIG. 15, except for the number and arrangement of device regions 301. In some cases, FIG. 16 may be considered a magnified view of the photonic interconnect structure 300 shown in FIG. 15. In some embodiments, a photonic interconnect structure 300 may have a length in the range of about 3000 μm to about 300000 μm or a width in the range of about 500 μm to about 100000 μm, though other dimensions are possible.

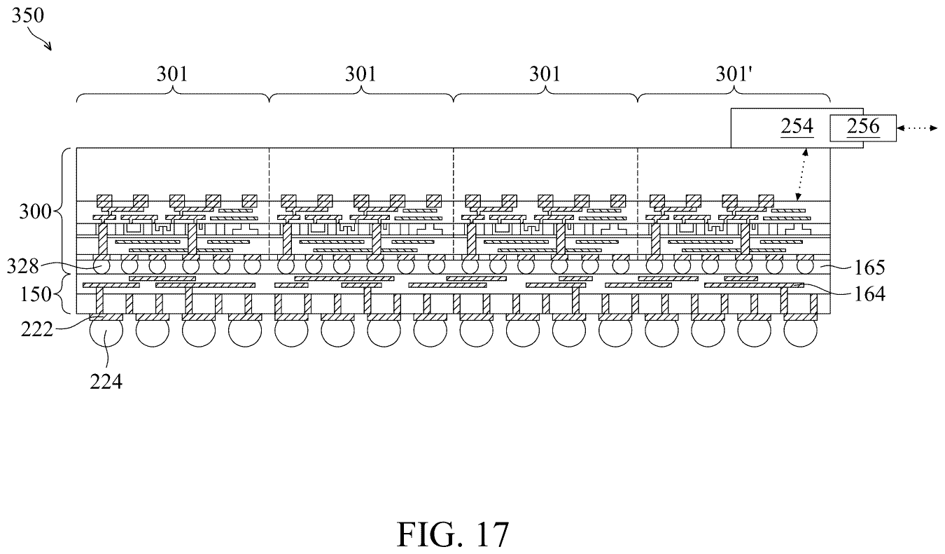

In FIG. 17, the photonic interconnect structure 300 is connected to an interposer 150 to form a photonic package 350, in accordance with some embodiments. The photonic package 350 may be similar to the photonic package 200 of FIG. 6, except that a photonic interconnect structure 300 is attached to the interposer 150 and dies 266 may be directly connected to the interposer 150, described in greater detail below. The interposer 150 may be similar to that described previously for FIG. 5. For example, the interposer 150 may include conductive features 164. Other package components (e.g., dies 266 or devices 270 of FIGS. 9-10) may also be connected to the interposer 150, described in greater detail below. As shown in FIG. 17, a fiber coupler 254 and/or an optical fiber 256 may be attached to a device region 301′ of the photonic package 350 to facilitate external optical communication.

In some embodiments, the conductive connectors 328 of the photonic interconnect structure 300 may be placed on corresponding conductive pads (not separately illustrated) of the interposer 150. A reflow process may then be performed to bond the conductive connectors 328 to the interposer 150. In this manner, the photonic interconnect structure 300 is physically and electrically connected to the interposer 150, and the interposer 150 may provide electrical interconnections between the photonic interconnect structure 300 and other package components. The interposer 150 may also provide electrical interconnections between device regions 301 of the photonic interconnect structure 300, in some embodiments. In some embodiments, an underfill 165 may be deposited between the photonic interconnect structure 300 and the interposer 150. In some embodiments, sidewalls of the photonic interconnect structure 300 and the interposer 150 may be substantially coplanar, as shown in FIG. 17. In other embodiments, sidewalls of the photonic interconnect structure 300 are offset from sidewalls of the interposer 150. Further in FIG. 17, conductive pads 222 and/or conductive connectors 224 may be formed on the interposer 150, which may be similar to those described previously.

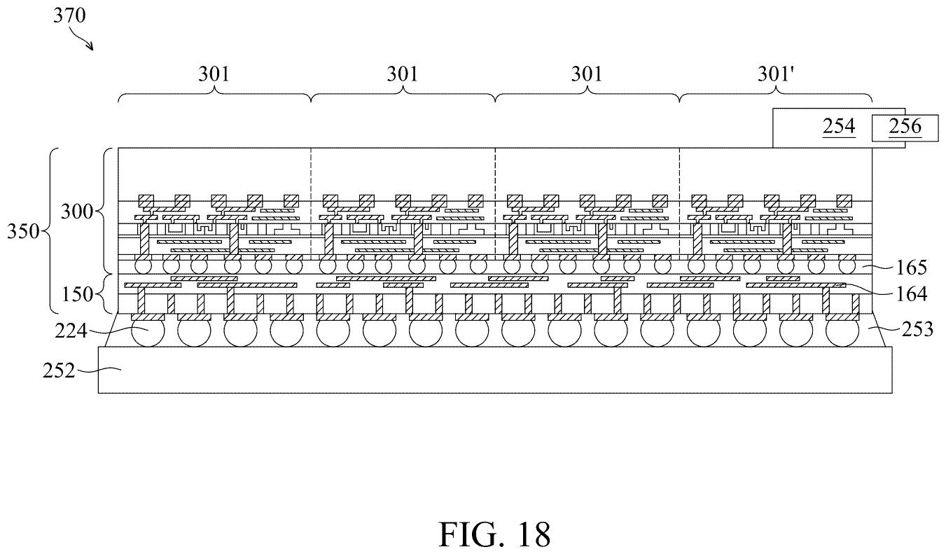

FIG. 18 illustrates the connection of a photonic package 350 to a package substrate 252 to form a photonic system 370, in accordance with some embodiments. The package substrate 252 may be similar to that described previously for FIG. 7. In some embodiments, an underfill 253 may be deposited between the photonic package 350 and the package substrate 252.

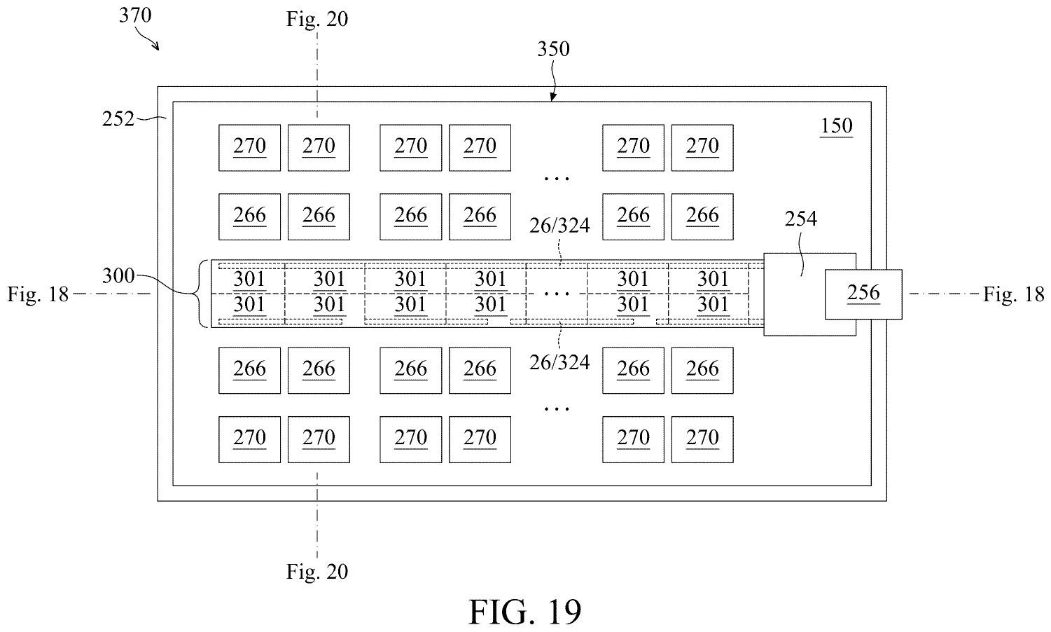

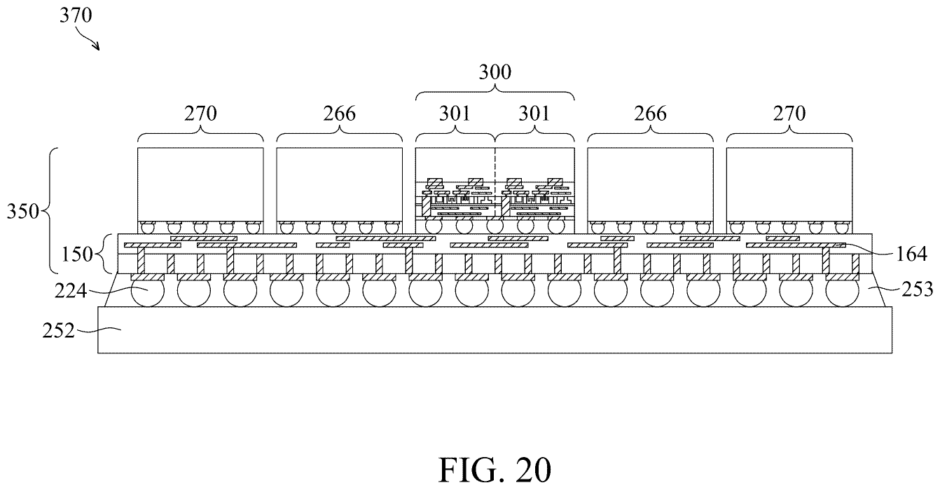

FIG. 19 illustrates a plan view of a photonic system 370, in accordance with some embodiments. The photonic system 370 of FIG. 19 may be similar to the photonic system 370 of FIG. 18, and a cross-section similar to the cross-sectional view of FIG. 18 is indicated in FIG. 19. FIG. 20 illustrates a cross-sectional view of a photonic system 370 similar to that of FIGS. 18-19, and a cross-section similar to the cross-sectional view of FIG. 20 is indicated in FIG. 19. The photonic system 370 comprises a photonic package 350 connected to a package substrate 252. The photonic package 350 comprises a photonic interconnect structure 300, dies 266, and devices 270 connected to an interposer 150. The photonic system 370 shown in FIGS. 19-20 is intended as an illustrative example, and other structures having other configurations, arrangements, dimensions, or features are possible. For clarity, some features are not shown in FIG. 19, such as conductive features 164 of the interposer 150, some waveguides 26 of the photonic interconnect structure 300, or the like.

The dies 266 and devices 270 may be similar to those described previously for the photonic system 250. For example, in some embodiments, the devices 270 may be HBM dies and the dies 266 may be xPU dies, though other devices, dies, or combinations thereof are possible. In some embodiments, the dies 266 and/or the devices 270 are connected to the interposer 150 by conductive connectors, which may be similar to conductive connectors described previously. In other embodiments, different numbers or other types of dies 266 and/or devices 270 may be connected to the interposer 150. In other embodiments, a photonic system 370 may comprise only either dies 266 or devices 270.

The photonic interconnect structure 300, the dies 266, and the devices 270 of the photonic package 350 are electrically connected by conductive features 164 within the interposer 150. The conductive features 164 may enable relatively short-distance communications within the photonic package 350 using electrical signals. For example, associated dies 266, devices 270, and device regions 301 may be electrically connected by the interposer 150. In some embodiments, waveguides 26 and/or 324 within the photonic interconnect structure 300 are utilized to transmit optical signals within the photonic package 350, such as optical signals transmitted between device regions 301. In this manner, the waveguides 26/324 may be used to provide relatively long-distance communications within the photonic package 350 using optical signals. In this manner, by using electrical signals over short distances through the interposer 150 and optical signals over long distances through the photonic interconnect structure 300, the efficiency, speed, and/or bandwidth of a photonic package 350 (or a photonic system 370) may be improved, and manufacturing cost may be reduced.

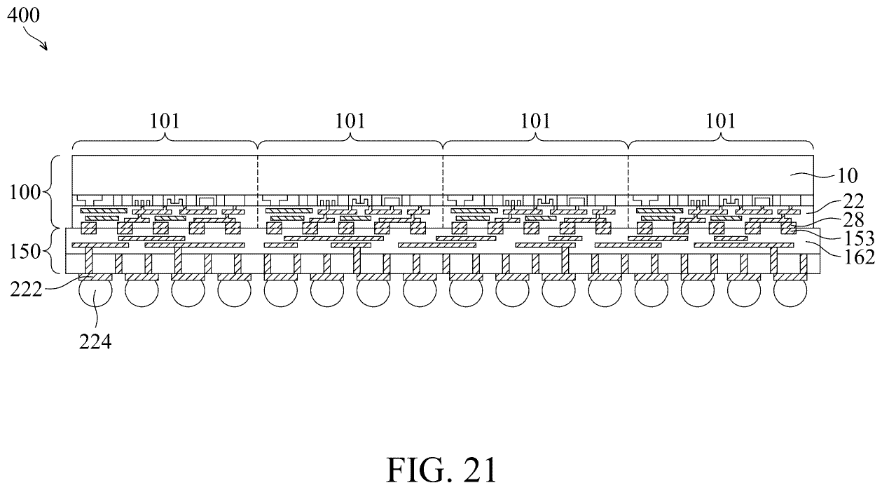

FIG. 21 illustrates a photonic package 400, in accordance with some embodiments. The photonic package 400 may be similar to the photonic package 200 described previously for FIG. 6, except that a photonic interconnect structure 100 is connected to an interposer 150 using dielectric-to-dielectric bonding and metal-to-metal bonding. The photonic interconnect structure 100 is similar to the photonic interconnect structure 100 of FIG. 6, except that the conductive pads 28 may be bond pads suitable for metal-to-metal bonding. The interposer 150 is similar to the interposer 150 of FIG. 6, except that the interposer 150 comprises bond pads 153 formed in the topmost dielectric layer 162. The conductive pads 28 may be bonded to the bond pads 153 using metal-to-metal bonding, such as that described previously for FIG. 13. A bonding layer of the dielectric layers 22 may be bonded to a bonding layer (e.g., the topmost layer) of the dielectric layers 162 using dielectric-to-dielectric bonding, such as that described previously for FIG. 13. Using metal-to-metal bonding and dielectric-to-dielectric bonding rather than conductive connectors in this manner can reduce package size, improve electrical connections, and improve device efficiency. Like other photonic packages described herein, the photonic package 400 may be connected to a package substrate 252 to form a photonic system.

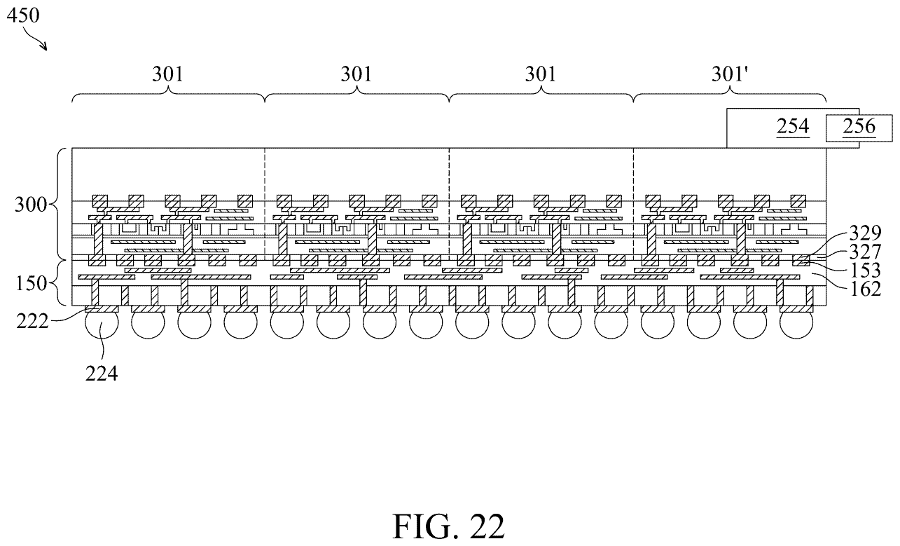

FIG. 22 illustrates a photonic package 450, in accordance with some embodiments. The photonic package 450 may be similar to the photonic package 350 described previously for FIG. 17, except that a photonic interconnect structure 300 is connected to an interposer 150 using dielectric-to-dielectric bonding and metal-to-metal bonding. The photonic interconnect structure 300 is similar to the photonic interconnect structure 300 of FIG. 17, except that the conductive pads 330 (for avowing repeating the UBM 329) may be bond pads suitable for metal-to-metal bonding and the passivation layer 327 may be a bonding layer suitable for dielectric-to-dielectric bonding. The interposer 150 is similar to the interposer 150 of FIG. 22. For example, the interposer 150 comprises bond pads 153 formed in the topmost dielectric layer 162. The conductive pads 330 (for avowing repeating the UBM 329) may be bonded to the bond pads 153 using metal-to-metal bonding, such as that described previously for FIG. 13. The passivation layer 327 may be bonded to a bonding layer (e.g., the topmost layer) of the dielectric layers 162 using dielectric-to-dielectric bonding, such as that described previously for FIG. 13. Using metal-to-metal bonding and dielectric-to-dielectric bonding rather than conductive connectors in this manner can reduce package size, improve electrical connections, and improve device efficiency. Like other photonic packages described herein, the photonic package 450 may be connected to a package substrate 252 to form a photonic system.

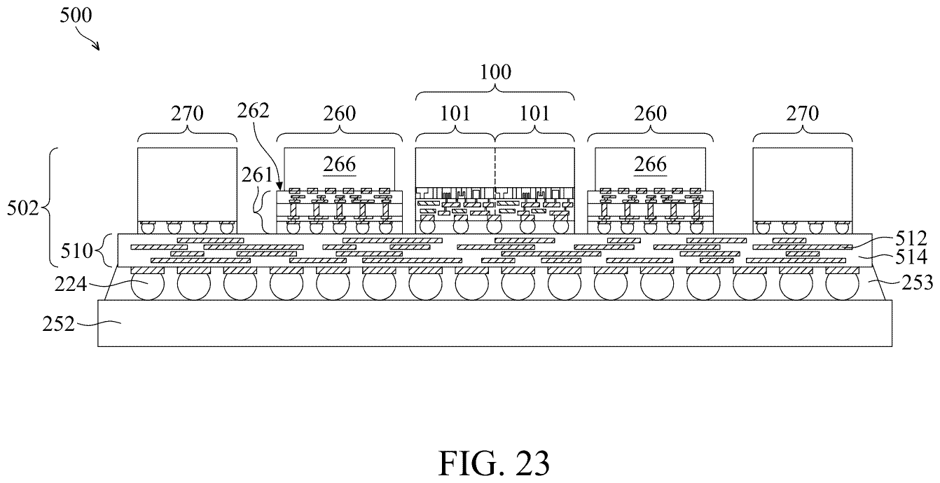

FIG. 23 illustrates a photonic system 500, in accordance with some embodiments. The photonic system 500 is similar to the photonic system 250 described for FIG. 10, except that a redistribution interposer 510 is used instead of an interposer 150. For example, the photonic system 500 comprises a photonic package 502, which comprises a photonic interconnect structure 100, package components 260, and devices 270 connected to the redistribution interposer 510. The photonic package 502 may be connected to a package substrate 252 using conductive connectors 224 or the like to form the photonic system 500.

The redistribution interposer 510 may be, for example, an organic interposer, a redistribution structure, or the like. The redistribution interposer 510 may include a plurality of redistribution layers 512 formed in a plurality of dielectric layers 514 (not individually illustrated). The redistribution layers 512 may include conductive lines, conductive vias, conductive pads, or the like. The redistribution layers 512 may be formed of a conductive material, such as a metal, such as copper, cobalt, aluminum, gold, combinations thereof, or the like. In some embodiments, the dielectric layers 514 may comprise a polymer such as polybenzoxazole (PBO), polyimide, a benzocyclobuten (BCB) based polymer, or the like. In other embodiments, the dielectric layers 514 may comprise other suitable dielectric materials, such as silicon oxide or the like. The redistribution layers 512 may be formed using any suitable process, such as deposition, plating, damascene, dual damascene, or the like. In some embodiments, the redistribution interposer 510 is substantially free of active and passive devices. In other embodiments, the redistribution interposer 510 includes waveguides formed in the dielectric layers 514. In some cases, the use of a redistribution interposer 510 may reduce manufacturing cost and package size.

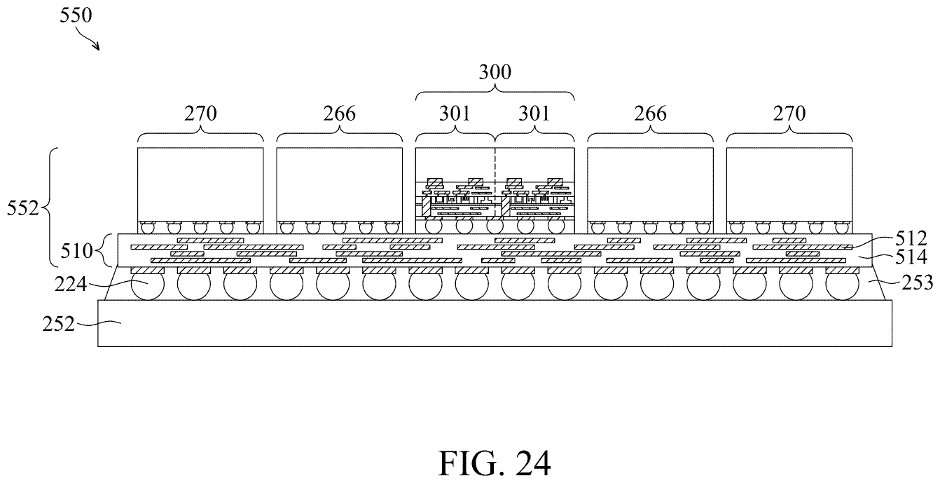

FIG. 24 illustrates a photonic system 550, in accordance with some embodiments. The photonic system 550 is similar to the photonic system 370 described for FIG. 20, except that a redistribution interposer 510 is used instead of an interposer 150. For example, the photonic system 550 comprises a photonic package 552, which comprises a photonic interconnect structure 300, dies 266, and devices 270 connected to the redistribution interposer 510. The redistribution interposer 510 may be similar to the redistribution interposer 510 described previously for FIG. 23. The photonic package 552 may be connected to a package substrate 252 using conductive connectors 224 or the like to form the photonic system 550.

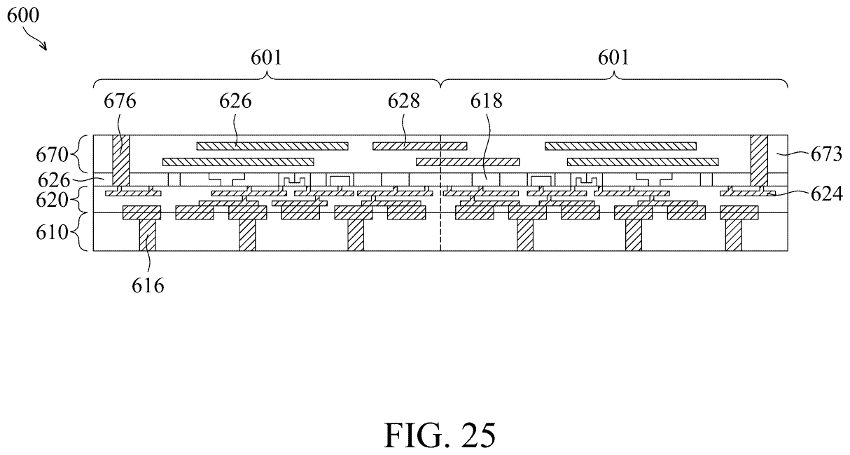

FIG. 25 illustrates a cross-sectional view of a photonic interconnect structure 600, in accordance with some embodiments. Some features of the photonic interconnect structure 600 may be similar to those of the photonic interconnect structure 100 and/or the photonic interconnect structure 300 described previously. For example, the photonic interconnect structure 600 comprises an interconnect structure 620 formed over photonic components 618 in a dielectric layer 626, in some embodiments. The photonic components 618 may be similar to the photonic components 18 described previously, and the dielectric layer 626 may be similar to the second insulator layer 16 described previously. The interconnect structure 620 may be similar to the interconnect structure 20 described previously, and may contain conductive features 624 that are electrically connected to the photonic components 618. An optical interconnect structure 670 may be formed over the photonic components 618 that comprise waveguides 628 formed in dielectric layers 673, which may be similar to the optical interconnect structure 320, waveguides 324, and dielectric layers 322 of the photonic interconnect structure 300. Vias 676 may be formed through the optical interconnect structure 670 that are electrically connected to the conductive features 624.

An electronic die 610 is bonded to the interconnect structure 620, in some embodiments. The electronic die 610 may be similar to the electronic die 310 described previously, and may provide similar functionality. Through vias 616 may extend through the electronic die 610, which may be electrically connected to the conductive features 624 in some cases. The electronic die 610 may be bonded to the interconnect structure 620 by metal-to-metal bonding and dielectric-to-dielectric bonding. In some embodiments, the photonic interconnect structure 600 comprises device regions 601. In this manner, the photonic interconnect structure 600 may be similar to the photonic interconnect structure 300, and may be formed using similar techniques.

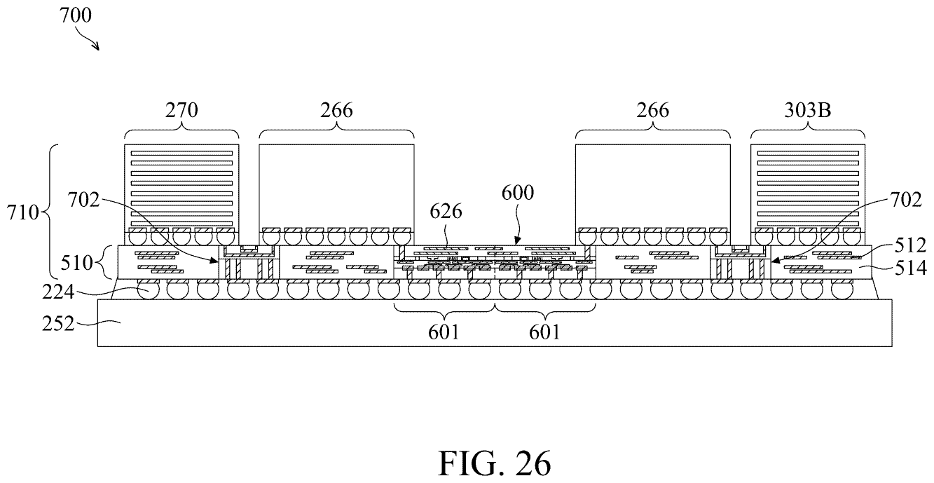

FIG. 26 illustrates a photonic system 700, in accordance with some embodiments. The photonic system 700 of FIG. 26 is similar to the photonic system 550 of FIG. 24, except that local interconnects 702 are formed in the redistribution interposer 510 and that a photonic interconnect structure 600 is formed within the redistribution interposer 510. A photonic package 710 may comprise a redistribution interposer 510, local interconnects 702 within the redistribution interposer 510, a photonic interconnect structure 600 within the redistribution interposer 510, dies 266 connected to the redistribution interposer 510, and device 270 connected to the redistribution interposer 510, in some embodiments. The photonic package 710 may be connected to a package substrate 252 by conductive connectors 224 or the like.

The local interconnects 702 may be, for example, chips, chiplets, local silicon interconnects, interconnect structures, or the like, that provide additional electrical interconnections within the redistribution interposer 510. For example, the local interconnects 702 may provide electrical connections between adjacent components, such as dies 266, devices 270, or the like. The local interconnects 702 may include conductive features (e.g., conductive lines, vias, pads, or the like) formed in dielectric layers. The conductive features may be formed using suitable techniques, such as damascene, dual damascene, or the like. For example, in some cases, a local interconnect 702 may comprise an interconnect structure on a substrate, which may have through-substrate vias (TSVs) within, though other local interconnects 702 are possible. In some cases, the conductive features of the local interconnects 702 may have a smaller linewidth and/or pitch than the redistribution layers 512 of the redistribution interposer 510, which can allow for a greater density of electrical routing. The local interconnects 702 may or may not include passive devices or active devices. The local interconnects 702 shown in FIG. 26 are illustrative examples, and other local interconnects 702 or configurations thereof are possible.

The photonic interconnect structure 600 is formed within the redistribution interposer 510 to provide electrical and optical communication within the photonic system 700. In some embodiments, one or more dies 266, devices 270, or the like may be connected to the photonic interconnect structure 600 by conductive connectors or metal-to-metal bonding. In some cases, a die 266 and/or device 270 may be connected to an associated device region 601 of the photonic interconnect structure 600. The photonic interconnect structure 600, the dies 266, and the devices 270 of the photonic package 710 are electrically connected by redistribution layers 512 within the redistribution interposer 510 and/or by local interconnects 702. In some embodiments, waveguides 628 within the photonic interconnect structure 600 are utilized to transmit optical signals within the photonic system 700, such as optical signals transmitted between device regions 601. For example, the waveguides 628 may be used to provide relatively long-distance communications within the photonic package 710 using optical signals. In this manner, by using electrical signals over short distances through the redistribution interposer 510 and local interconnects 702 and using optical signals over long distances through the photonic interconnect structure 600, the efficiency, speed, and/or bandwidth of the photonic system 700 may be improved, and manufacturing cost may be reduced.

In some embodiments, the local interconnects 702 and the photonic interconnect structure 600 may be placed on a carrier substrate (not illustrated) and then the redistribution interposer 510 may be formed around the local interconnects 702 and the photonic interconnect structure 600. In other embodiments, the redistribution interposer 510 may be formed first and the local interconnects 702 and the photonic interconnect structure 600 then placed into openings formed in the redistribution interposer 510. In some embodiments, top surfaces of the local interconnects 702, the photonic interconnect structure 600, and/or the redistribution interposer 510 may be substantially level or coplanar.

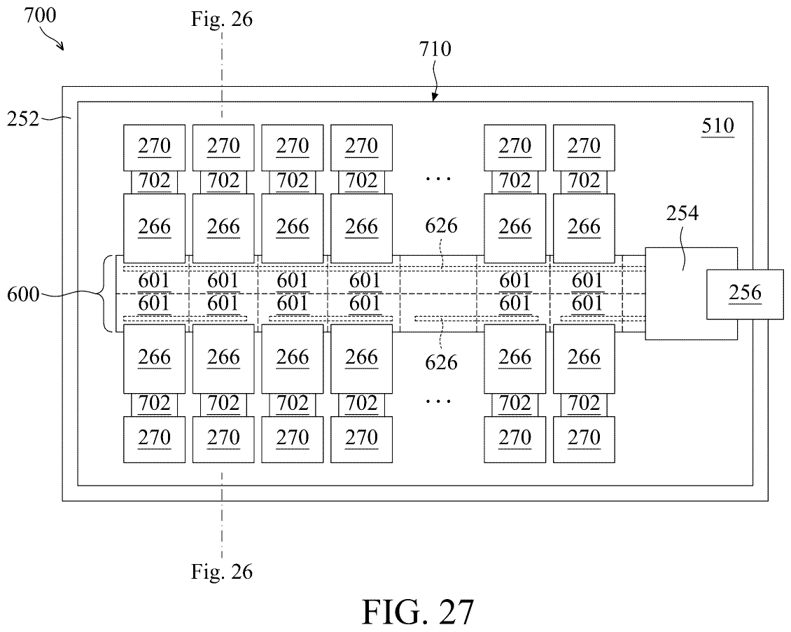

FIG. 27 illustrates a plan view of a photonic system 700, in accordance with some embodiments. The photonic system 700 of FIG. 27 may be similar to the photonic system 700 of FIG. 26, and a cross-section similar to the cross-sectional view of FIG. 26 is indicated in FIG. 27. The photonic system 700 comprises a photonic package 710 connected to a package substrate 252. The photonic package 710 comprises a photonic interconnect structure 600 and local interconnects 702 within a redistribution interposer 510, and dies 266 and devices 270 connected to the redistribution interposer 510. In some embodiments, a fiber coupler 254 and/or optical fiber 256 may be optically coupled to the photonic interconnect structure 600. The photonic system 700 shown in FIG. 27 is intended as an illustrative example, and other structures having other configurations, arrangements, dimensions, or features are possible. For clarity, some features are not shown in FIG. 27.

Embodiments of the present disclosure have some advantageous features. By using electrical signals over short distances and optical signals over long distances, the efficiency, speed, and/or bandwidth of a device, package, or structure may be improved. The use of a photonic interconnect structure as described herein can enable intra-package optical communication. A single photonic structure may include multiple device regions, which can take the place of multiple photonic dies. Forming multiple device regions within a single structure can reduce manufacturing cost, reduce package size, and enable optical communication between various dies or devices of a package. This can allow for more dies or devices to be optically connected within a single package. In some cases, some of the photonic interconnect structures described herein may be considered “monolithic” structures. The embodiments described herein can facilitate both electrical communication and optical communication within a package, which can improve performance and efficiency.

In an embodiment of the present disclosure, a package includes an interposer; a photonic interconnect structure connected to the interposer, wherein the photonic interconnect structure includes: photonic components; waveguides that are optically coupled to the photonic components; and an electronic die that is electrically coupled to the photonic components; and dies electrically connected to the interposer, wherein the dies are electrically coupled to the photonic interconnect structure through the interposer. In an embodiment, the photonic interconnect structure is connected to the interposer through solder bumps. In an embodiment, the photonic interconnect structure is connected to the interposer through dielectric-to-dielectric bonds and metal-to-metal bonds. In an embodiment, the waveguides are silicon nitride waveguides. In an embodiment, the interposer includes conductive redistribution layers in polymer dielectric layers. In an embodiment, the package includes a fiber array unit attached to the electronic die, wherein the fiber array unit is optically coupled to the waveguides. In an embodiment, the dies are electrically coupled to respectively corresponding separate device regions of the photonic interconnect structure. In an embodiment, the device regions of the photonic interconnect structure respectively include corresponding regions of the electronic die and corresponding sets of photonic components.

In an embodiment of the present disclosure, a package includes a photonic structure connected to an interconnect structure, wherein the photonic structure includes a first device region, a second device region, and a waveguide, wherein the first device region includes a first photonic component, wherein the second device region includes a second photonic component, wherein the first device region is optically coupled to the second device region by the waveguide; a first package component connected to the interconnect structure, wherein the first package component is electrically coupled to the first device region; and a second package component connected to the interconnect structure, wherein the second package component is electrically coupled to the second device region. In an embodiment, the first package component includes a first integrated circuit die and a second integrated circuit die bonded to an active interposer. In an embodiment, the first integrated circuit die is electrically coupled to the first device region of the photonic structure and the second integrated circuit die is electrically coupled to a third device region of the photonic structure. In an embodiment, the first package component is a first semiconductor die and the second package component is a second semiconductor die. In an embodiment, the photonic structure includes a glass substrate. In an embodiment, the first photonic component and the second photonic component are formed on a substrate, wherein the first device region and the second device region respectively include different portions of the substrate, wherein the substrate is free of passive devices and active devices. In an embodiment, the substrate is a glass substrate. In an embodiment, the photonic structure includes an electronic die, wherein a first portion of the electronic die within the first device region is electrically coupled to the first photonic component and a second portion of the electronic die within the second device region is electrically coupled to the second photonic component. In an embodiment, the first package component is electrically coupled to the first photonic component and the second package component is electrically coupled to the second photonic component.

In an embodiment of the present disclosure, a method includes forming a photonic interconnect structure, including: forming first waveguides; forming photonic components over the first waveguides; forming an interconnect structure over the photonic components; and bonding an electronic die to the interconnect structure; bonding the photonic interconnect structure to an interposer; and bonding semiconductor dies to the interposer, wherein the semiconductor dies are electrically connected to the photonic interconnect structure. In an embodiment, the method includes forming second waveguides within the interconnect structure. In an embodiment, bonding the photonic interconnect structure includes performing a fusion bonding process. In an embodiment, the method includes bonding the interposer to a package substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package comprising:
a photonic interconnect structure comprising:
an interconnect structure comprising a plurality of conductive features and a plurality of waveguides; and
a plurality of photonic components over the interconnect structure, wherein the plurality of photonic components are electrically coupled to the plurality of conductive features, wherein at least one waveguide of the plurality of waveguides is optically coupled to a first photonic component of the plurality of photonic components and to a second photonic component of the plurality of photonic components;
an interposer, wherein the interconnect structure is connected to a first side of the interposer; and
a plurality of first dies connected to the first side of the interposer, wherein each first die of the plurality of first dies is electrically coupled to a respective photonic component of the plurality of photonic components.

2. The package of claim 1, wherein the plurality of photonic components comprises an optical modulator.

3. The package of claim 1, wherein the first photonic component and the second photonic components are near opposite ends of the photonic interconnect structure.

4. The package of claim 1, wherein the photonic interconnect structure further comprises a substrate over the plurality of photonic components, wherein the substrate is free of active or passive devices.

5. The package of claim 1 further comprising a plurality of second dies on each first die.

6. The package of claim 1 further comprising a fiber coupler attached to the photonic interconnect structure, wherein the fiber coupler is optically coupled to at least one photonic component.

7. The package of claim 1, wherein the plurality of waveguides comprises silicon nitride waveguides.

8. The package of claim 1, wherein the photonic interconnect structure comprises a plurality of device regions, wherein each device region comprises a same type of photonic component.

9. A structure comprising:
an interposer comprising:
a photonic interconnect comprising:
a plurality of photonic components; and
a plurality of waveguides; and
a redistribution structure surrounding the photonic interconnect;
a plurality of electronic dies on the interposer, wherein each electronic die overlaps the redistribution structure and the photonic interconnect, wherein each electronic die is electrically connected to the redistribution structure and to the photonic interconnect.

10. The structure of claim 9, wherein the interposer further comprises a plurality of local interconnects surrounded by the redistribution structure, wherein each electronic die overlaps a respective local interconnect, wherein each electronic die is electrically connected to the respective local interconnect.

11. The structure of claim 9, wherein each electronic die is electrically connected to a respective photonic component.

12. The structure of claim 9, wherein each electronic die is connected to the photonic interconnect by at least one conductive connector.

13. The structure of claim 9, wherein top surfaces of the redistribution structure and the photonic interconnect are level.

14. The structure of claim 9, wherein each electronic die is associated with a respective device region of the photonic interconnect, wherein each device region of the photonic interconnect comprises at least one photonic component.

15. The structure of claim 14, wherein at least one waveguide extends between two device regions.

16. A method comprising:
forming a plurality of photonic components over a top side of a substrate;
forming an interconnect structure over a top side of the plurality of photonic components, wherein the interconnect structure is electrically coupled to the plurality of photonic components;
bonding an integrated circuit die to a top side of the interconnect structure, wherein the integrated circuit die comprises a plurality of device regions, wherein each device region is electrically coupled to a photonic component underneath that device region;
removing the substrate; and
forming a plurality of first waveguides over a bottom side of the plurality of photonic components, wherein at least one first waveguide is optically coupled to at least one photonic component;
forming a plurality of conductive connectors over a bottom side of the plurality of first waveguides; and
bonding the plurality of conductive connectors to an interposer.

17. The method of claim 16 further comprising connecting a plurality of electronic dies to the interposer adjacent the plurality of conductive connectors.

18. The method of claim 17, wherein each electronic die is electrically coupled to a corresponding respective device region of the integrated circuit die.

19. The method of claim 16, wherein the interconnect structure comprises a plurality of third waveguides.

20. The method of claim 16, wherein the plurality of photonic components comprises at least one fourth waveguide.
